(19) United States
(12) Patent Application Publication
(10) Pub. No.: US 2001/0046733 A1
(43) Pub. Date: Nov. 29, 2001

(54) SEMICONDUCTOR DEVICE HAVING ELECTRICAL DIVIDED SUBSTRATE AND METHOD FOR FABRICATING THE SEMICONDUCTOR DEVICE

(76) Inventors: MASATO TAKITA, KAWASAKI-SHI (JP); MASATO MATSUMIYA, KAWASAKI-SHI (JP)

Correspondence Address: ARENT FOX KINTNER PLOTKIN & KAHN, PLLC, 1050 CONNECTICUT AVENUE NW SUITE 600, WASHINGTON, DC, 20036-5339, US

(21) Appl. No.: 09/046,671

(22) Filed: Mar. 24, 1998

(30) Foreign Application Priority Data
Sep. 22, 1997 (JP) 09-257085/1997

(51) Int. Cl. H01L 21/8234; H01L 21/8244

(52) U.S. Cl. 438/238

(57) ABSTRACT

The semiconductor device comprises a semiconductor substrate 14 of a first conduction type; a buried semiconductor layer 38b of a second conduction type formed in a first region of the semiconductor substrate 14, spaced from a surface of the semiconductor substrate 14; a semiconductor region 38a of a second conduction type formed in a peripheral portion of a region between the surface of the semiconductor substrate 14 in the first region of the semiconductor substrate 14 and the buried semiconductor layer 38b, and connected to the buried semiconductor layer 38b; and a semiconductor region 14a of the first conduction type formed in the semiconductor substrate 14 surrounded by the buried semiconductor layer 38b and the second conduction type semiconductor region 38a. The parasitic capacitance between the source/drain diffused layer of the input/output transistor and the semiconductor substrate can be small, whereby the semiconductor device can have high operational speed. The leak current from the capacitor through the junction between the source/drain diffused layer of the transistor of the cell unit and the first conduction type semiconductor region can be small, with a result that frequent rewriting operations for retaining a charge of the capacitor are not necessary, and the semiconductor device can have small electric power consumption.

### BACKGROUND OF THE INVENTION

The present invention relates to a semiconductor device and a method for fabricating the same, more specifically a semiconductor device having small electric power consumption and high operational speed.

The recent operational speed-up of information equipments is remarkable, but as information processing amount increases, it is required that semiconductor devices to be used in the information equipments have further higher operational speed. It is strongly required that battery lives of the portable information equipments be elongated. The semiconductor devices are required to have further small electric power consumption.

FIG. 28 is a block diagram of a DRAM (Dynamic Random Access Memory) widely used in information equipments.

The DRAM is a semiconductor memory using capacitors as memory cells, and one memory cell includes one transistor and one capacitor and takes accordingly only a small area. The DRAM is a semiconductor memory suitable to have capacities increased.

A DRAM mainly comprises an input/output unit 110 for inputting/outputting address signals, data signals and control signals, a control unit 128 for performing a required control of writing/reading information or others, based on a signal from the input/output unit 110, a cell unit 146 including memory cells for storing information formed in a matrix.

The input/output unit 110 includes an input transistor 210 for inputting address signals and control signals from the outside, an input/output transistor 212 for inputting/outputting data from/to the outside, etc. Row address signals for selecting word lines (not shown) and column address signals for selecting bit lines (not shown) are alternately inputted in the input transistor 210. This method is called address multiplex method, and address signal terminals are decreased to a half by the use of this method.

The control unit 128 includes an address input circuit 214 for inputting an address signal from the input transistor 210, a control input circuit 216 for inputting a control signal from the input transistor 210, a row address buffer 218 for outputting a row address signal, a column address buffer 220 for outputting a column address signal, a row decoder 222 for selecting a word line, a column decoder 224 for selecting a bit line, a sense amplifier 226 for amplifying a signal read from a memory cell (not shown), a data control circuit 228 for controlling, as required, inputted/outputted data, and a buffer 230 for inputting/outputting data in/from the input/output transistor 212.

An address signal inputted to the input transistor 210 is inputted to the row address buffer 218 and the column address buffer 220 via the address input circuit 214. To judge whether the inputted address signal is a row address signal or a column address signal, a control signal indicating that the inputted address signal is a row address signal or a column signal is inputted to the row address buffer 218 and the column address buffer 220 via the control input circuit 216.

When a prescribed control signal is inputted in the row address buffer 218, the row address buffer 218 outputs to the row decoder 222 the inputted address signal as a row address signal. The row decoder 222 selects a specific word line, based on the inputted row address signal.

On the other hand, when a prescribed control signal is inputted to the column address buffer 220, the column address buffer 220 outputs to the column decoder 224 the inputted address signal as a column address signal. The column decoder 224 selects a specific bit line, based on the inputted column address signal.

The cell unit 146 includes a memory cell array 232 of memory cells formed in a matrix. Each memory cell comprises one capacitor for storing information and one transistor for storing information or reading information in and from the capacitor. The transistors are controlled by the word lines and the bit lines to write/read information in/from the capacitors.

Each bit line includes the sense amplifier 226 which is a flip-flop amplifier, and a signal read from a memory cell is amplified by the sense amplifier 226. The signal amplified by the sense amplifier 226 is outputted outside via the input/output buffer 230 and the input/output transistor 212.

The conventional DRAM shown in FIG. 28 will be further detailed with reference to FIG. 29. In FIG. 29, for convenience, apart of constituent members of the respective units are shown, and the DRAM includes a p-semiconductor substrate 114.

As shown in FIG. 29, the input/output unit 110 includes an n-channel input/output transistor 112, and the control unit 128 includes an n-channel transistor 130 and a p-channel transistor 132 which form a C-MOS (Complementary-Metal Oxide Semiconductor) invertor. The cell unit 146 includes an n-channel transistor 148 for writing information in the capacitors and reading information stored in the capacitors.

The input/output unit 110 includes an input/output transistor 112 which comprises a gate electrode 118 formed on a p-semiconductor substrate 114 through an oxide film (not shown) and a source/drain diffused layer 116a, 116b formed by implanting an n-impurity with the gate electrode 118 as a mask.

The source/drain diffused layer 116a of the input/output transistor 112 is connected to a pad 120 which is an input/output terminal. It is necessary to match a voltage to be applied to the input/output transistor 112 with an outside voltage, and the semiconductor substrate 114 is connected to a ground voltage Vss through a contact layer 124 heavily doped with a p-impurity. Because the input/output transistor 112 is formed on the lightly doped semiconductor substrate 114, a capacitor between the source/drain diffused layer 116a of the input/output transistor 112 and the semiconductor substrate 114 is small, which makes high speed operation possible.

The control unit 128 includes an n-channel transistor 130 which comprises a gate electrode 136 formed on the semiconductor substrate through an insulation film (not shown), and a source/drain diffused layer 134a, 134b formed by implanting an n-impurity with the gate electrode 136 as a mask.

An n-well 138 doped with an n-impurity is formed in a region near the surface of the semiconductor substrate 114 in a region where an n-channel transistor 132 is to be formed. A transistor 132 comprising above the n-well 138 a gate electrode 142 formed through an insulation film (not shown), and a source/drain diffused layer 140a, 140b formed by implanting a p-impurity with the gate electrode 142 as a mask is formed on the n-well 138. It is necessary that a voltage applied to the transistor 132 matches with a voltage of a source voltage Vdd, and the n-well 138 is connected to the source voltage Vdd through a contact layer 144 heavily doped with an n-impurity.

An n-well 138 is formed, extended in a region near the surface of the semiconductor substrate 114 in a region where a transistor 148 of the cell unit 146 is to be formed. In the n-well 138 in the region for the transistor 148 to be formed in a p-well 164 is formed by implanting a high concentration of boron ions, which are a p-impurity. On the p-well 164, transistor 148 comprising a gate electrode 152 formed above the p-well 164 through an insulation film (not shown), and a source/drain diffused layer 150a, 150b formed by implanting a high concentration of an n-impurity is formed. The source/drain diffused layer 150b of the transistor 148 is connected to a capacitor 154, and the p-well 164 is connected to a voltage Vbb which is lower than a ground voltage Vss, through a contact layer 158 heavily doped with a p-impurity.

However, in the conventional DRAM as shown in FIG. 29, the p-well 164 of the cell unit 146 is formed by implanting a high concentration of a p-impurity in a part of the n-well 138 doped with an n-impurity, with an advertent result that leak current from the capacitor 154 through the junction between the source/drain diffused layer 150a, 150b of the transistor 148 is much. Consequently, to maintain a charge of the capacitor 154 rewriting operations must be frequently performed, which increases power consumption.

To make leak current of the transistor 148 of the cell unit 146 small it can be proposed that the transistor 148 of the cell unit 146 is formed on the lightly doped semiconductor substrate 114, a p-well is formed by implanting a high concentration of a p-impurity in a part of the n-well having an n-impurity implanted, and the input/output transistor 112 of the input/output unit 110 is formed on the p-well. Forming the input/output transistor 112 on the heavily doped p-well adversely increases parasitic capacitance between the source/drain diffused layer 116a and the p-well, which makes high-speed operation impossible.

Then what is proposed here is to form the input/output transistor 112 of the input/output unit 110 and the transistor 148 of the cell unit 146 on the semiconductor substrate 114. However, a voltage of the input/output transistor 112 of the input/output unit 110 is matched with a voltage from the outside, and to this end the semiconductor substrate must be connected to the ground voltage Vss. To increase threshold voltage to make the leak current small it is necessary that the semiconductor substrate is connected to the voltage Vbb which is lower than the ground voltage Vss. To this end, unpractically the semiconductor substrate forming the input/output transistor 112 of the input/output unit 110 is isolated from the semiconductor substrate forming the transistor 148 of the cell unit 146.

### SUMMARY OF THE INVENTION

An object of the present invention is to provide a semiconductor device having small electric power consumption and high operational speed, and a method for fabricating the semiconductor device.

The above-described object is achieved by a semiconductor device comprising: a semiconductor substrate of a first conduction type; a buried semiconductor layer of a second conduction type formed in a first region of the semiconductor substrate, spaced from a surface of the semiconductor substrate; a semiconductor region of the second conduction type extending from the surface of the semiconductor substrate to a peripheral portion of the buried semiconductor layer; and a semiconductor region of the first conduction type formed in the semiconductor substrate surrounded by the buried semiconductor layer and the semiconductor region of the second conduction type. The input/output transistor of the input/output unit can be formed on the semiconductor substrate in the region different from the first region, whereby a parasitic capacitance between the source/drain diffused layer of the input/output transistor and the semiconductor substrate can be small, whereby the semiconductor device can have high operational speed. The transistor of the cell unit can be formed on the first conduction type semiconductor region which is electrically isolated from the semiconductor substrate, whereby a voltage lower than a ground voltage of the semiconductor substrate is applied to the first conduction type semiconductor region, whereby a threshold voltage value of the transistor of the cell unit can be set high, and a leak current from the capacitor through the junction between the source/drain diffused layer of the transistor of the cell unit and the first conduction type semiconductor region can be small, with a result that frequent rewriting operations for retaining a charge of the capacitor are not necessary, and the semiconductor device can have small electric power consumption. The input/output transistor of the input/output unit is formed on the first conduction type semiconductor region electrically isolated from the semiconductor substrate, and the transistor of the cell unit can be formed on the semiconductor substrate which is free from damage by the impurity ion implantation, whereby leak current from the capacitor through the junction between the source/drain diffused layer of the transistor of the cell unit and the semiconductor substrate can be little, and frequent rewriting operations for retaining a charge of the capacitor are not necessary, and the semiconductor device can have small electric power consumption.

In the above-described semiconductor device, it is preferable that the semiconductor device further comprises a first semiconductor element formed in the first conduction type region; and a second semiconductor element formed in a second region different from the first region of the semiconductor substrate, the first conduction type semiconductor region being connected to a first potential, the second region of the semiconductor substrate being connected to a second potential different from the first potential.

In the above-described semiconductor device, it is preferable that the second conduction type semiconductor region is extended over a third region adjacent to the first region of the semiconductor substrate; the semiconductor device further comprises a third semiconductor element formed in the third region of the second conduction type semiconductor region; and the second conduction type semiconductor region is connected to a third potential different at least the first potential or the second potential.

In the above-described semiconductor device, it is preferable that the semiconductor device further comprises a well of the first conduction type formed in a fourth region in the third region; and a fourth semiconductor element formed in the first conduction type well, and the first conduction type well being connected to a fourth potential different from at least the first potential. The input/output transistor of the input/output unit can be formed on the first conduction type semiconductor region, and the transistor of the control unit can be formed on the first conduction type well which is electrically isolated from the first conduction type semiconductor region, whereby the first conduction type semiconductor region and the first conduction type well can be connected to respective voltage, and even when an abnormal voltage of, e.g., minus, is applied, the transistor of the control unit can be prevented from performing erroneous operations. Accordingly, in a case that the transistor of the control unit is used for controlling the transistor of the cell unit, the transistor of the control unit is prevented from performing erroneous operations due to such abnormal voltages, and information of the memory cell is prevented from breakage.

In the above-described semiconductor device, it is preferable that the first semiconductor element and/or the second semiconductor element is a memory cell.

The above-descried object is achieved by a method for fabricating a semiconductor device comprising: a buried semiconductor layer forming step of implanting at first energy impurity ions of a second conduction type in a first region of a semiconductor substrate of a first conduction type to form a buried semiconductor layer of the second conduction type in the semiconductor substrate, spaced from a surface of the semiconductor substrate; and a second conduction type semiconductor region forming step of implanting impurity ions of the second conduction type in a peripheral portion of the first region of the semiconductor device at second energy which is lower than the first energy to form a semiconductor region of the second conduction type extended to the buried semiconductor layer. The input/output transistor of the input/output unit can be formed on the semiconductor substrate in the region different from the first region, whereby a parasitic capacitance between the source/drain diffused layer of the input/output transistor and the semiconductor substrate can be small, and the semiconductor device can have high operational speed. The transistor of the cell unit can be formed on the first conduction type semiconductor region electrically isolated from the semiconductor substrate, whereby a lower voltage than a ground voltage of the semiconductor substrate is applied to the first conduction type semiconductor region to set a threshold voltage value of the transistor of the cell unit to be high. With a result that leak current from the capacitor through the junction between the source/drain diffused layer of the transistor of the cell unit and the first conduction type semiconductor region can be small, and frequent rewriting operations for retaining a charge of the capacitor are not necessary, and the semiconductor device can have small electric consumption.

The above-described object is achieved by a method for fabricating a semiconductor device comprising: a buried semiconductor layer forming step of implanting at first energy impurity ions of a second conduction type in a first region of a first conduction type semiconductor substrate to form a buried semiconductor layer of the second conduction type in the semiconductor substrate, spaced from a surface of the semiconductor substrate; a second conduction type semiconductor region forming step of implanting impurity ions of the second conduction type in a peripheral portion of the first region of the semiconductor device at second energy which is lower than the first energy to form a semiconductor region of the second conduction type in a region which is deep to a prescribed level from the surface of the semiconductor substrate; and a heat treatment step of performing a heat treatment to diffuse the impurity ions in the buried semiconductor layer and in the second conduction type semiconductor region to connect the buried semiconductor layer and the second conduction type semiconductor region with each other. The input/output transistor of the input/output unit can be formed on the semiconductor substrate in the region different from the first region, whereby a parasitic capacitance between the source/drain diffused layer of the input/output transistor and the semiconductor substrate can be small, whereby the method for fabricating a semiconductor device can provide a semiconductor device having high operational speed. The transistor of the cell unit can be formed on he first conduction type semiconductor region which is electrically isolated from the semiconductor substrate, whereby a voltage lower than a ground voltage of the semiconductor substrate is applied to the first conduction type semiconductor region, whereby a threshold voltage value of the transistor of the cell unit can be set high, and a leak current from the capacitor through the junction between the source/drain diffused layer of the transistor of the cell unit and the first conduction type semiconductor region can be little with a result that frequent rewriting operations for retaining a charge of the capacitor are not necessary, and the semiconductor device can have small electric power consumption.

The above-described object is achieved by a method for fabricating a semiconductor device comprising: a second conduction type semiconductor region forming step of implanting impurity ions of a second conduction type at first energy in a peripheral portion of a first region of a semiconductor substrate of a first conduction type to form a semiconductor region of the second conduction type in a region which is deep to a prescribed level from a surface of the semiconductor substrate; a heat treatment step of performing a heat treatment to diffuse the impurity ions in the second conduction type semiconductor region; and a buried semiconductor layer forming step of implanting impurity ions of the second conduction type in the first region of the semiconductor substrate at second energy which is higher than the first energy to form a buried semiconductor layer of the second conduction type connected to the second conduction type semiconductor region, spaced from the surface of the semiconductor substrate. The input/output transistor of the input/output unit can be formed on the semiconductor substrate in the region different from the first region, whereby a parasitic capacitance between the source/drain diffused layer of the input/output transistor and the semiconductor substrate can be small, and the method for fabricating a semiconductor device can provide a semiconductor device having high operational speed. The transistor of the cell unit can be formed on the first conduction type semiconductor region electrically isolated from the semiconductor substrate, whereby a lower voltage than a ground voltage of the semiconductor substrate is applied to the first conduction type semiconductor region to set a threshold voltage value of the transistor of the cell unit to be high. With a result that leak current from the capacitor through the junction between the source/drain diffused layer of the transistor of the cell unit and the first conduction type semiconductor region can be small, and frequent rewriting operations for retaining a charge of the capacitor are not necessary, and the method for fabricating a semiconductor device can provide a semiconductor device having small electric consumption.

The above-described object is achieved by a method for fabricating a semiconductor device comprising: a second conduction type semiconductor region forming step of implanting impurity ions of a second conduction type at first energy in a peripheral portion of a first region of a semiconductor substrate of a first conduction type to form a semiconductor region of the second conduction type in a region which is deep to a prescribed level from a surface of the semiconductor substrate; a buried semiconductor layer forming step of implanting impurity ions of the second conduction type in the first region of the semiconductor substrate at a second energy which is higher than the first energy to form a buried semiconductor layer of the second conduction type spaced form the surface of the semiconductor substrate; and a heat treatment step of performing a heat treatment to diffuse the impurity ions in the second conduction type semiconductor region and in the buried semiconductor layer to connect the second conduction type semiconductor region and the buried semiconductor layer with each other. The input/output transistor of the input/output unit can be formed on the semiconductor substrate in the region different from the first region, whereby a parasitic capacitance between the source/drain diffused layer of the input/output transistor and the semiconductor substrate can be small, and the method for fabricating a semiconductor device can provide a semiconductor device having high operational speed. The transistor of the cell unit can be formed on the first conduction type semiconductor region electrically isolated from the semiconductor substrate, whereby a lower voltage than a ground voltage of the semiconductor substrate is applied to the first conduction type semiconductor region to set a threshold voltage value of the transistor of the cell unit to be high. With a result that leak current from the capacitor through the junction between the source/drain diffused layer of the transistor of the cell unit and the first conduction type semiconductor region can be small, and frequent rewriting operations for retaining a charge of the capacitor are not necessary, and the method for fabricating a semiconductor device can provide a semiconductor device having small electric consumption.

The above-described object is achieved by a method for fabricating a semiconductor device comprising: a second conduction type semiconductor region forming step of implanting impurity ions of a second conduction type at first energy in a peripheral portion of a first region of a semiconductor substrate of a first conduction type at first energy to form a semiconductor region of the second conduction type, then implanting impurity ions of the second conduction type in the peripheral portion at second energy which is higher than the first energy to form the second conduction type semiconductor region deeper from the surface of the semiconductor substrate; and a buried semiconductor layer forming step of implanting impurity ions of the second conduction type in the first region of the semiconductor substrate at third energy which is higher than the second energy to form a buried semiconductor layer of the second conduction type connected to the second conduction type semiconductor region, spaced from the surface of the semiconductor substrate. The input/output transistor of the input/output unit can be formed on the semiconductor substrate in the region different from the first region, whereby a parasitic capacitance between the source/drain diffused layer of the input/output transistor and the semiconductor substrate can be small, and the method for fabricating a semiconductor device can provide a semiconductor device having high operational speed. The transistor of the cell unit can be formed on the first conduction type semiconductor region electrically isolated from the semiconductor substrate, whereby a lower voltage than a ground voltage of the semiconductor substrate is applied to the first conduction type semiconductor region to set a threshold voltage value of the transistor of the cell unit to be high. With a result that leak current from the capacitor through the junction between the source/drain diffused layer of the transistor of the cell unit and the first conduction type semiconductor region can be small, and frequent rewriting operations for retaining a charge of the capacitor are not necessary, and the method for fabricating a semiconductor device can provide a semiconductor device having small electric consumption.

In the above-described method for fabricating a semiconductor device, it is preferable that in the second conduction type semiconductor region forming step, a semiconductor region of the second conduction type is also formed in a second region which is adjacent to the first region of the semiconductor substrate.

In the above-described method for fabricating a semiconductor device, it is preferable that the method for fabricating a semiconductor device further comprises a well forming step of implanting a high concentration of impurity ions of the first conduction type in a prescribed region of the second region to form a well of the first conduction type.

### BRIEF DESCRIPTION OF THE DRAWINGS

FIG. 1 is a sectional view and a plan view of the semiconductor device according to a first embodiment of the present invention.

FIG. 2 is sectional views of the semiconductor device according to the first embodiment in the steps of the method for fabricating the same (Part 1), which show the method (Part 1).

FIG. 3 is sectional views of the semiconductor device according to the first embodiment in the steps of the method for fabricating the same (Part 1), which show the method (Part 2).

FIG. 4 is sectional views of the semiconductor device according to the first embodiment in the steps of the method for fabricating the same (Part 2), which show the method (Part 1).

FIG. 5 is sectional views of the semiconductor device according to the first embodiment in the steps of the method for fabricating the same (Part 2), which show the method (Part 2).

FIG. 6 is sectional views of the semiconductor device according to the first embodiment in the steps of the method for fabricating the same (Part 3), which show the method (Part 1).

FIG. 7 is sectional views of the semiconductor device according to the first embodiment in the steps of the method for fabricating the same (Part 3), which show the method (Part 2).

FIG. 8 is sectional views of the semiconductor device according to the first embodiment in the steps of the method for fabricating the same (Part 4), which show the method (Part 1).

FIG. 9 is sectional views of the semiconductor device according to the first embodiment in the steps of the method for fabricating the same (Part 4), which show the method (Part 2).

FIG. 10 is a sectional view and a plan view of the semiconductor device according to a second embodiment of the present invention.

FIG. 11 is sectional views of the semiconductor device according to the second embodiment in the steps of the method for fabricating the same (Part 1), which show the method (Part 1).

FIG. 12 is sectional views of the semiconductor device according to the second embodiment in the steps of the method for fabricating the same (Part 1), which show the method (Part 2).

FIG. 13 is sectional views of the semiconductor device according to the second embodiment in the steps of the method for fabricating the same (Part 2), which show the method (Part 1).

FIG. 14 is sectional views of the semiconductor device according to the second embodiment in the steps of the method for fabricating the same (Part 2), which show the method (Part 2).

FIG. 15 is sectional views of the semiconductor device according to the second embodiment in the steps of the method for fabricating the same (Part 3), which show the method (Part 1).

FIG. 16 is sectional views of the semiconductor device according to the second embodiment in the steps of the method for fabricating the same (Part 3), which show the method (Part 2).

FIG. 17 is sectional views of the semiconductor device according to the second embodiment in the steps of the method for fabricating the same (Part 4), which show the method (Part 1).

FIG. 18 is sectional views of the semiconductor device according to the second embodiment in the steps of the method for fabricating the same (Part 4), which show the method (Part 2).

FIG. 19 is a sectional view and a plan view of the semiconductor device according to a third embodiment of the present invention.

FIG. 20 is sectional views of the semiconductor device according to the third embodiment in the steps of the method for fabricating the same (Part 1), which show the method (Part 1).

FIG. 21 is sectional views of the semiconductor device according to the third embodiment in the steps of the method for fabricating the same (Part 1), which show the method (Part 2).

FIG. 22 is sectional views of the semiconductor device according to the third embodiment in the steps of the method for fabricating the same (Part 2), which show the method (Part 1).

FIG. 23 is sectional views of the semiconductor device according to the third embodiment in the steps of the method for fabricating the same (Part 2), which show the method (Part 2).

FIG. 24 is sectional views of the semiconductor device according to the third embodiment in the steps of the method for fabricating the same (Part 3), which show the method (Part 1).

FIG. 25 is sectional views of the semiconductor device according to the third embodiment in the steps of the method for fabricating the same (Part 3), which show the method (Part 2).

FIG. 26 is sectional views of the semiconductor device according to the third embodiment in the steps of the method for fabricating the same (Part 4), which show the method (Part 1).

FIG. 27 is sectional views of the semiconductor device according to the third embodiment in the steps of the method for fabricating the same (Part 4), which show the method (Part 2).

FIG. 28 is a block diagram of the conventional DRAM, which shows a constitution thereof.

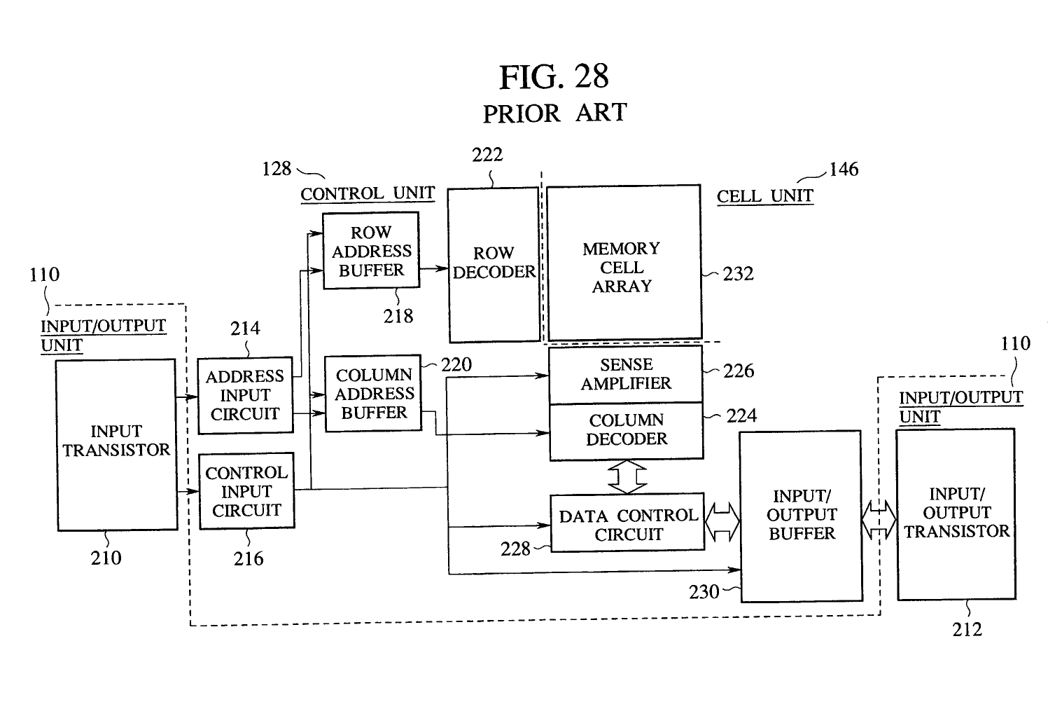

FIG. 29 is a sectional view and a plan view of the conventional DRAM.

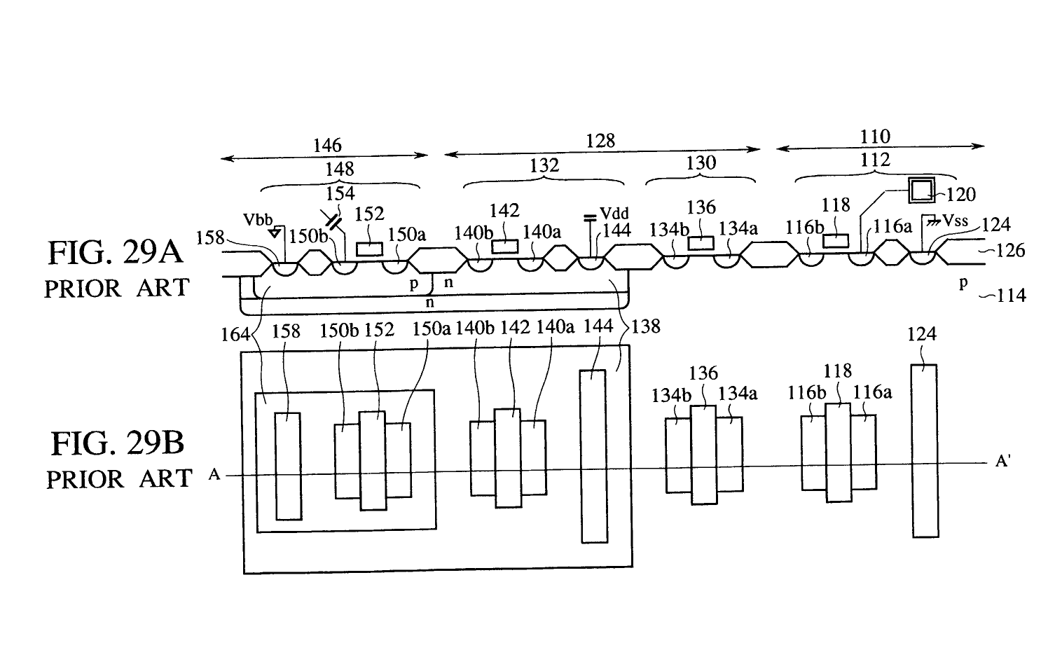

### DETAILED DESCRIPTION OF THE INVENTION

[A First Embodiment]

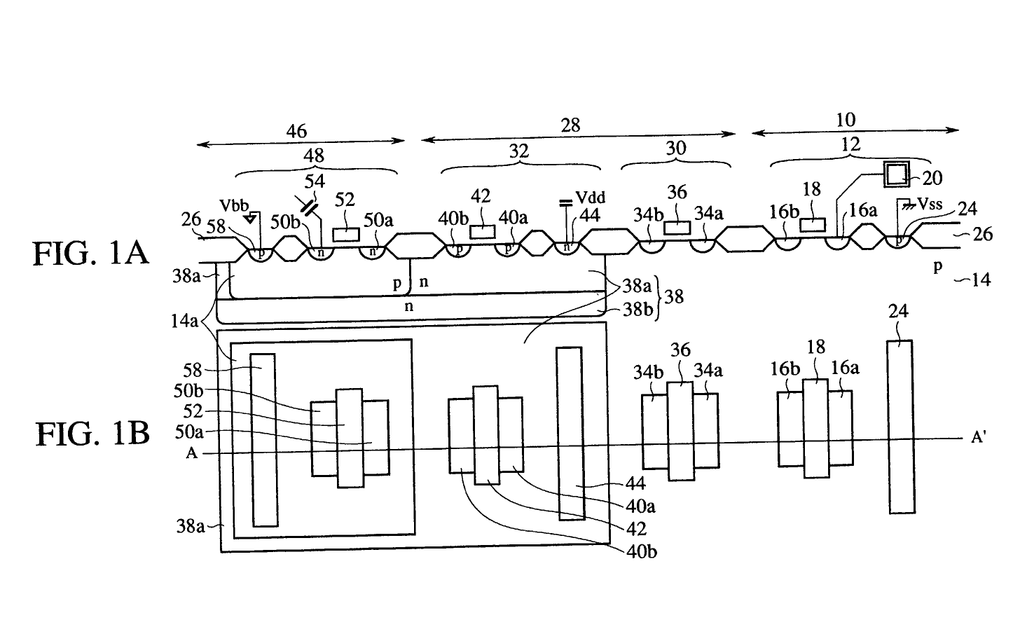

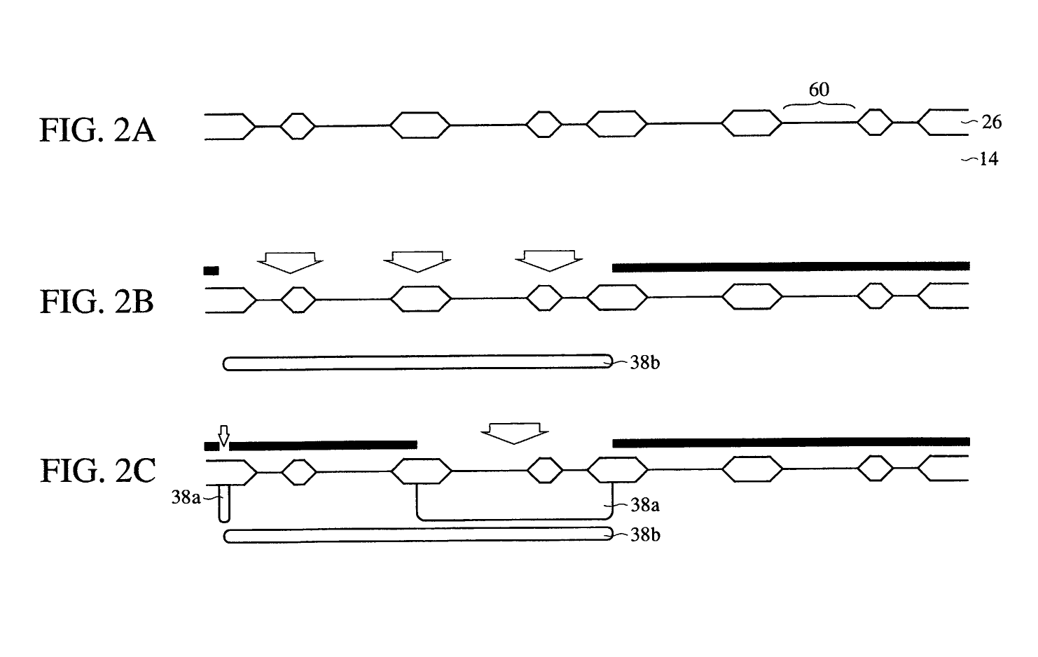

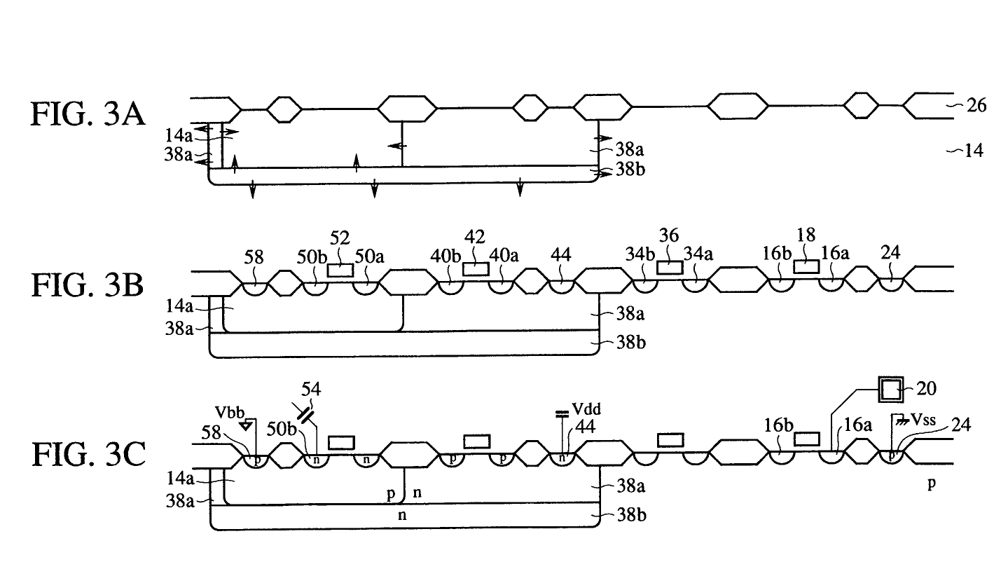

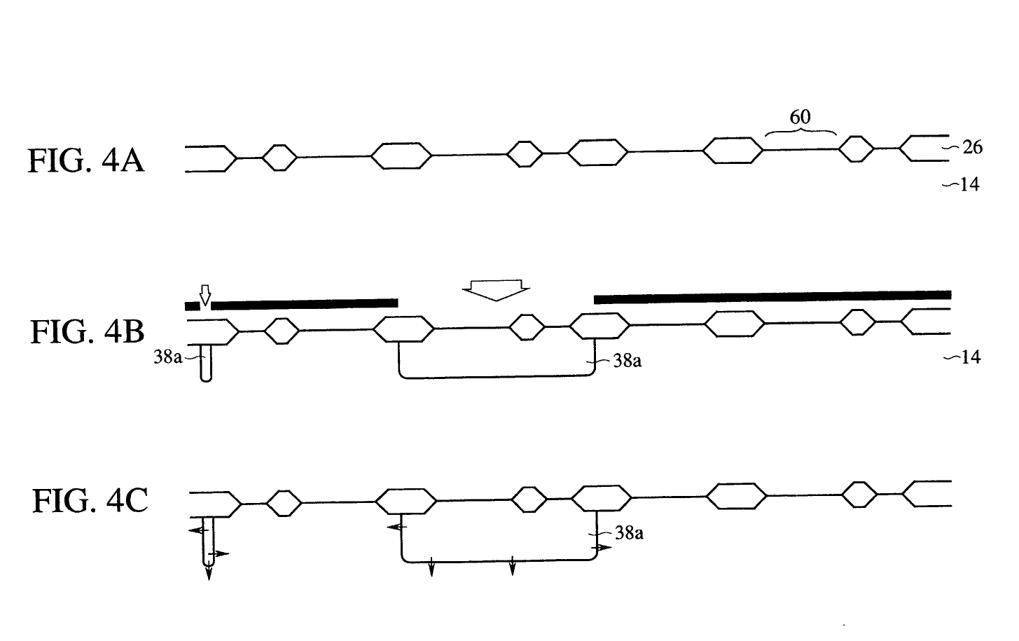

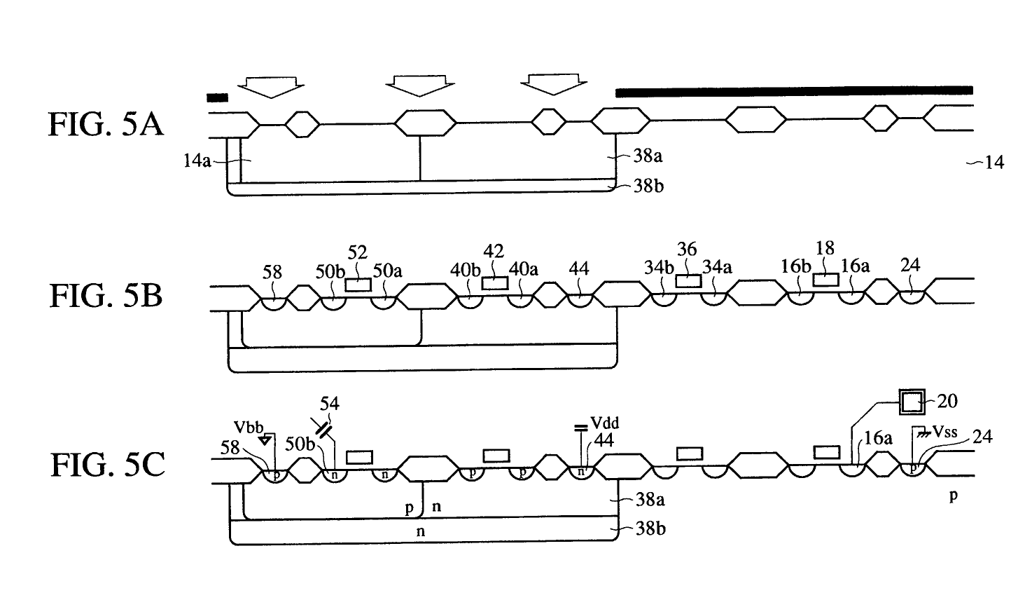

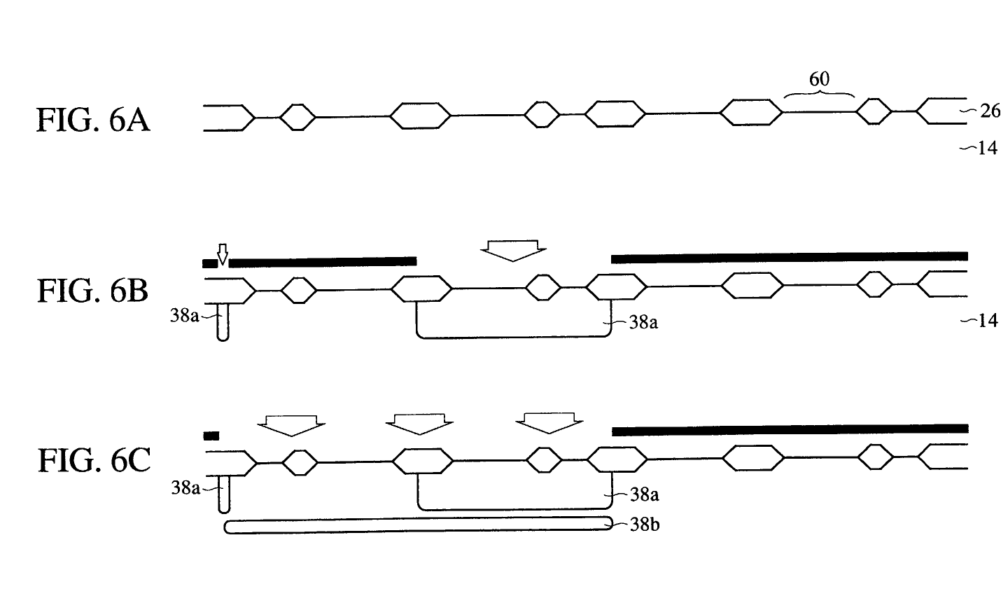

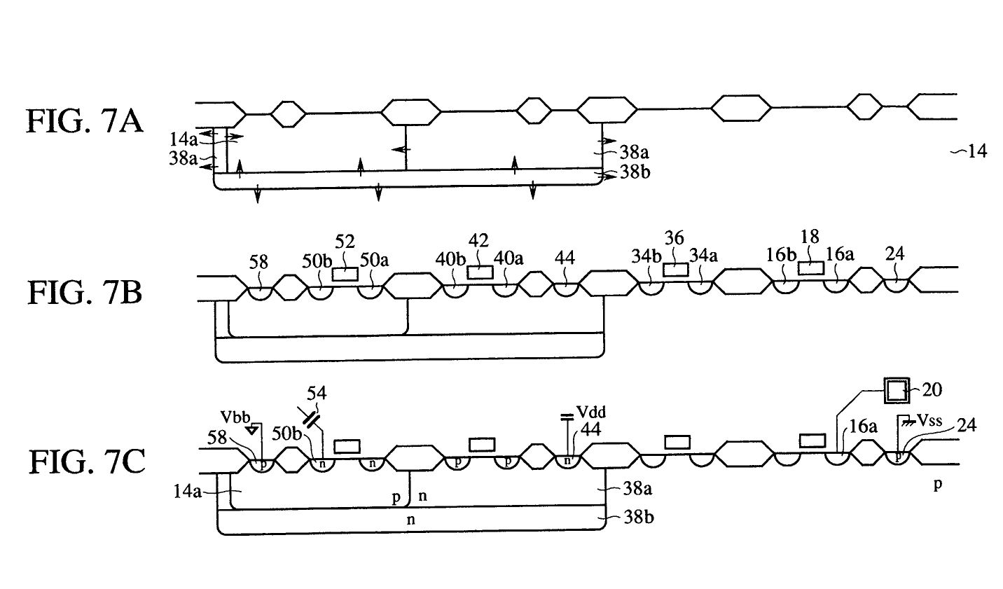

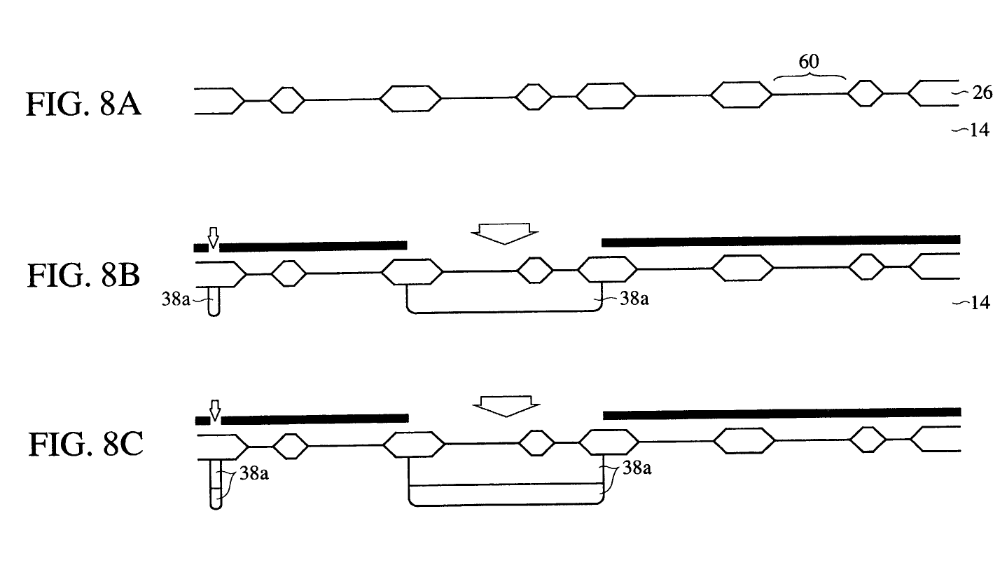

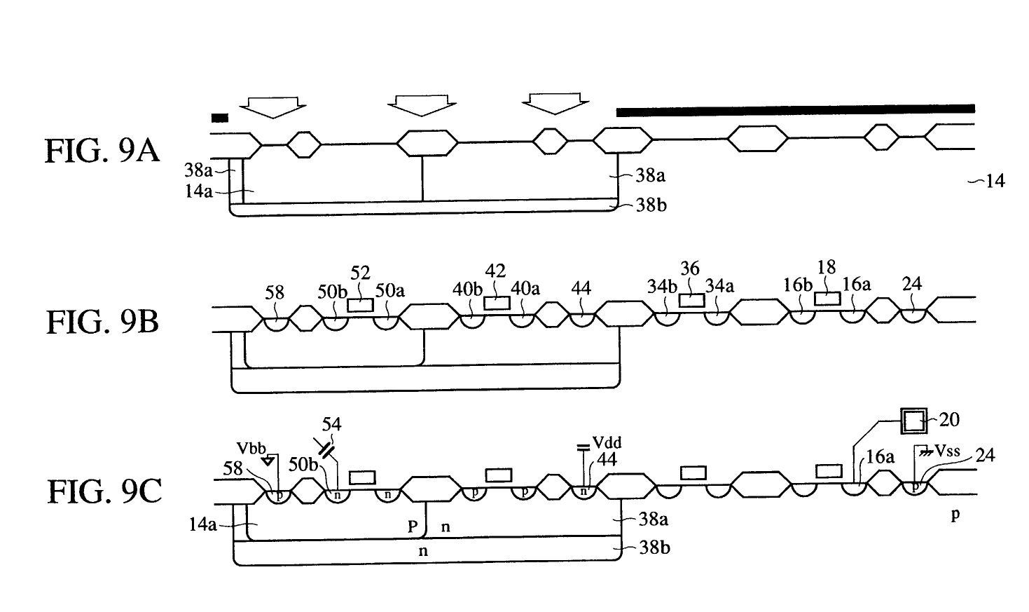

The semiconductor device according to a first embodiment of the present invention and the method for fabricating the semiconductor device will be explained with reference to FIGS. 1 to 9. FIG. 1 is a sectional view and a plan view of the semiconductor device according to the present embodiment. FIG. 1A is the sectional view along the line A-A′ in FIG. 1B. FIG. 1B is the plan view in which constituent members, such as a device isolation film, etc., are omitted for convenience of explanation. FIGS. 2 and 3 are sectional views of the semiconductor device according to the present embodiment in the steps of the method for fabricating the semiconductor device, which explain the method (Part 1). FIGS. 4 and 5 are sectional views of the semiconductor device according to the present embodiment in the steps of the method for fabricating the semiconductor device, which explain the method (Part 2). FIGS. 6 and 7 are sectional views of the semiconductor device according to the present embodiment in the steps of the method for fabricating the semiconductor device, which explain the method (Part 3). FIGS. 8 and 9 are sectional views of the semiconductor device according to the present embodiment in the steps of the method for fabricating the semiconductor device, which explain the method (Part 4).

As shown in FIG. 1, the semiconductor device according to the present embodiment comprises an input/output unit 10 for inputting/outputting address signals, data signals and control signals, etc., a control unit 28 for performing prescribed controls, as of writing and reading information, based on signals from the input/output unit 10, etc., and a cell unit 46 including memory cells for storing information in a matrix. FIG. 1 shows only major constituent members for convenience of explanation.

In the input/output unit 10 there is formed an input/output transistor 12 comprising a gate electrode 18 formed on a p-semiconductor substrate 14 through an oxide film (not shown), and a source/drain diffused layer 16a, 16b formed by implanting an n-impurity with the gate electrode 18 as a mask. The source/drain diffused layer 16a is connected to a pad 20 which is an input/output terminal. The input/output transistor 12 is for inputting/outputting address signals, data signals, control signals, etc.

A voltage applied to the input/output transistor 12 must match with an outside voltage, and the semiconductor substrate 14 is connected to a ground voltage Vss through a doped contact layer 24 heavily doped with a p-impurity. Because the input/output transistor 12 is formed on the lightly doped semiconductor substrate 14, a parasitic capacitance between the source/drain diffused layer 16a and the semiconductor substrate 14 is small, which enables high-speed operation.

In the control unit 28 there are formed an n-channel transistor 30 and a p-channel transistor 32 which constitute a C-MOS invertor, etc.

The n-channel transistor 30 comprises a gate electrode 36 formed on the semiconductor substrate 14 through an insulation film (not shown), a source/drain diffused layer 34a, 34b formed by implanting an n-impurity with the gate electrode 36 as a mask.

An n-semiconductor region 38a doped with an n-impurity is formed in a region near the surface of the semiconductor substrate 14 in a region where a p-channel transistor 32 is formed. In the n-doped semiconductor region 38a there is formed a transistor 32 comprising a gate electrode 42 formed through an insulation film (not shown), and a source/drain diffused layer 40a, 40b formed by implanting a p-impurity with the gate electrode 42 as a mask. A voltage applied to the transistor 32 must be matched with a voltage of a source voltage Vdd, and the n-semiconductor region 38a is connected the source voltage Vdd through a contact layer 44 heavily doped with an n-impurity.

The n-semiconductor region 38a is extended over the peripheral portion of a region near the surface of the semiconductor substrate 14 in a region where a transistor 48 of the cell unit 46 is formed. On the semiconductor device 14 in the regions where the transistors 32, 48 are formed there is formed a buried n-semiconductor layer 38b spaced from the surface of the semiconductor substrate 14 by implanting n-impurity ions at high energy of some MeV. The semiconductor substrate 14 in the region where the transistor 48 is formed is electrically isolated from the semiconductor substrate 14 in the other regions by the n-semiconductor region 38a and the buried n-semiconductor layer 38b and is a p-semiconductor region 14a.

The transistor 48 is formed on the p-semiconductor region 14a and comprises a gate electrode 52 formed through an insulation film (not shown) and a source/drain diffused layer 50a, 50b formed by heavily implanting an n-impurity with the gate electrode 52 as a mask. A capacitor 54 for storing information is connected to the source/drain diffused layer 50b of the transistor 48. To set a threshold voltage of the transistor 48 high, the p-semiconductor region 14a is connected to a voltage Vbb which is lower than the ground voltage Vss, through a contact layer 58 heavily doped with a p-impurity.

As described above, according to the present embodiment, the input/output transistor of the input/output unit is formed on the lightly doped semiconductor substrate, whereby a parasitic capacitance between the source-drain diffused layer and the semiconductor substrate can be made small, and the semiconductor device can have high operational speed.

According to the present embodiment, the n-semiconductor region and the buried n-semiconductor layer are formed so that the semiconductor substrate in a prescribed region where the transistor of the cell unit is formed is electrically isolated from the semiconductor substrate in the other regions, and the transistor of the cell unit is formed on the p-semiconductor region of the semiconductor substrate in the prescribed isolated region, whereby a threshold voltage of the transistor of the cell unit can be set high by applying to the p-semiconductor region a voltage Vbb which is lower than a ground voltage Vss of the semiconductor substrate, and leak current from the capacitor through the junction between the source-drain diffused layer and the p-semiconductor region of the cell unit can be made little. Accordingly, the semiconductor device can have infrequent rewriting operations for maintaining a charge of the capacitor, and small electric power consumption.

[Method for Fabricating the Semiconductor Device according to the First Embodiment (Part 1)]

Then, the method for fabricating the semiconductor device according to the first embodiment will be explained with reference to FIGS. 2 and 3.

First, a device isolation film 26 is formed on a p-semiconductor substrate 14 to form an active region 60 (see FIG. 2A)

Next, n-impurity ions are implanted at high energy of some MeV by the use of a mask of a pattern which is opened in regions where the p-channel transistor 32 of the control unit 28 and the transistor 48 of the cell unit 46 to thereby form the buried n-semiconductor layer 38b in a region spaced from the surface of the semiconductor substrate 14 (see FIG. 2B).

Then n-impurity ions are implanted at energy of hundreds keV by the use of a mask of a pattern which is opened in the peripheral portion of a region for the transistor 48 of the cell unit to be formed in, and a region for the p-channel transistor 32 of the control unit 28 to be formed in to form the n-semiconductor region 38a in a region from the surface of the semiconductor substrate 14 to the vicinity of the buried n-semiconductor layer 38b (see FIG. 2C).

Then, the n-impurities in the n-semiconductor region 38a and the buried n-semiconductor layer 38b are diffused by heat-treatment to connect the n-semiconductor region 38 and the buried n-semiconductor layer 38b with each other. The p-semiconductor region 14a is electrically isolated from the semiconductor substrate 14 by the n-semiconductor region 38a and the buried n-semiconductor layer 38b (see FIG. 3A).

Then, an oxide film (not shown) is formed on the entire surface of the semiconductor substrate 14 and is etched by the use of a mask patterned in shapes of the gate electrodes 18, 36, 42, 52 to form the gate electrodes 18, 36, 42, 52. Then, n-impurity ions are implanted with the gate electrodes 18, 36, 52 as a mask to form the source/drain diffused layer 16a, 16b, 34a, 34b, 50a, 50b. Then, a p-impurity is implanted with the gate electrode 42 as a mask to form the source/drain diffused layer 40a, 40b . Then, p-impurity ions are implanted by the use of a mask patterned in shapes of the contact layers 24, 58 to form the contact layers 24, 58. Then, n-impurity ions are implanted by the use of a mask patterned in a shape of the contact layer 44 to form the contact layer 44 (see FIG. 3B).

Next, an insulation film (not shown) is formed on the entire surface of the semiconductor substrate 14. Then, contact holes are formed on the source/drain diffused layer 16a, 50b and on the contact layers 24, 44, 58. Next, wiring is performed by aluminum vapor deposition or others to connect the source/drain diffused layer 16a to the pad 20, the source/drain diffused layer 50b to a capacitor 54, and the contact layers 24, 44, 58 respectively to the prescribed voltages Vss, Vdd, Vbb (see FIG. 3C).

The semiconductor device according to the present embodiment is thus fabricated.

[Method for Fabricating the Semiconductor Device according to the First Embodiment (Part 2)]

Then, the method for fabricating the semiconductor device according to the present embodiment (Part 2) will be explained with reference to FIGS. 4 and 5.

The method for fabricating the semiconductor device according to the present embodiment (Part 2) is characterized by forming the active region 60 (see FIG. 4A), then forming the n-semiconductor region 38a (see FIG. 4B), next diffusing an n-impurity in the n-semiconductor region 38a (see FIG. 4C), and then forming the buried n-semiconductor layer 38b connected to the n-semiconductor region 38a to electrically isolate the p-semiconductor region 14a from the p-substrate 14 (see FIG. 5A).

The method for fabricating the semiconductor device according to the present embodiment (Part 2) has a different order of the fabrication steps of the method for fabricating the semiconductor device according to the present embodiment (Part 1) but is the same as the latter in forming the respective constituent elements.

[Method for Fabricating the Semiconductor Device according to the First Embodiment (Part 3)]

The method for fabricating the semiconductor device according to the present embodiment (Part 3) will be explained with reference to FIGS. 6 and 7.

The method for fabricating the semiconductor device according to the first embodiment (Part 3) is characterized by forming the active region 60 (see FIG. 6A), then forming the n-semiconductor region 38a (see FIG. 6B), next forming the buried n-semiconductor layer 38b (see FIG. 6C), and diffusing the n-impurities in the n-semiconductor region 38a and the buried n-semiconductor layer 38b to thereby connect the n-semiconductor region 38a and the buried n-semiconductor layer 36b with each other to electrically isolate the p-semiconductor region 14a from the semiconductor substrate 14 (see FIG. 7A).

The method for fabricating the semiconductor device according to the present embodiment (Part 3) has a different order of the fabrication steps of the method for fabricating the semiconductor device according to the present embodiment (Part 1) but is the same as the latter in forming the respective constituent elements.

[Method for Fabricating the Semiconductor Device according to the First Embodiment (Part 4)]

The method for fabricating the semiconductor device according to the present embodiment (Part 4) will be explained with reference to FIGS. 8 and 9.

The method for fabricating the semiconductor device according to the first embodiment (Part 4) is characterized by forming the active region 60 (see FIG. 8A), then forming the n-semiconductor region 38a (see FIG. 8B), implanting an n-impurity at high energy to form the n-semiconductor region 38a deep from the surface of the semiconductor substrate 14 (see FIG. 8C), and then forming the buried n-semiconductor layer 38b connected to the n-semiconductor region 38a to electrically isolate the p-semiconductor region 14a from the semiconductor substrate 14 (see FIG. 9A). Because the n-semiconductor region 38a is formed deep from the surface of the semiconductor substrate 14a, the n-semiconductor region 38a and the buried n-semiconductor layer 38b can be connected with each other without diffusing the impurities by heat-treatment.

The method for fabricating the semiconductor device according to the present embodiment (Part 4) has a different order of the fabrication steps of the method for fabricating the semiconductor device according to the present embodiment (Part 1) but is the same as the latter in forming the respective constituent elements.

[A Second Embodiment]

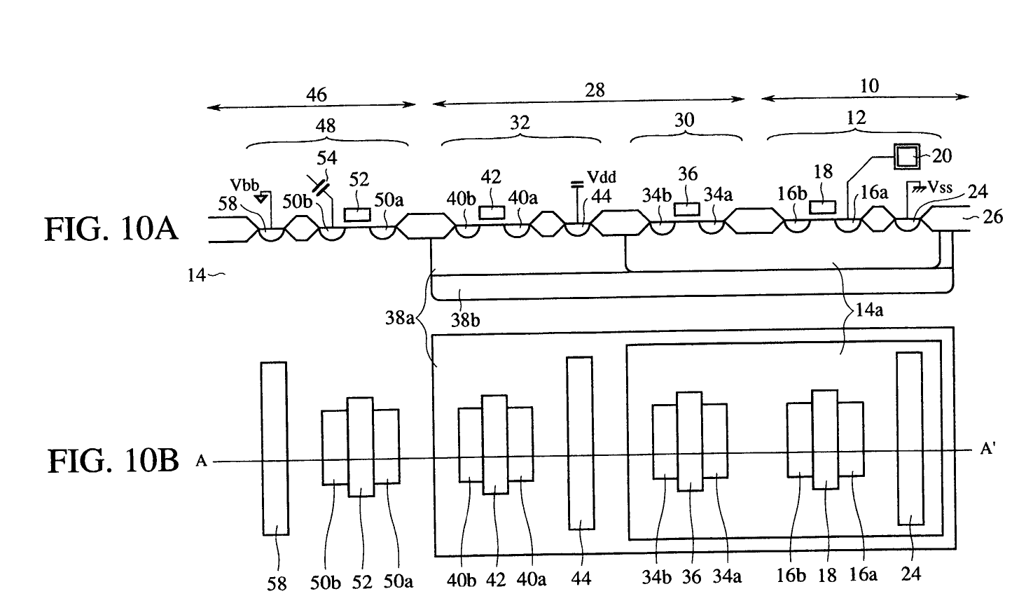

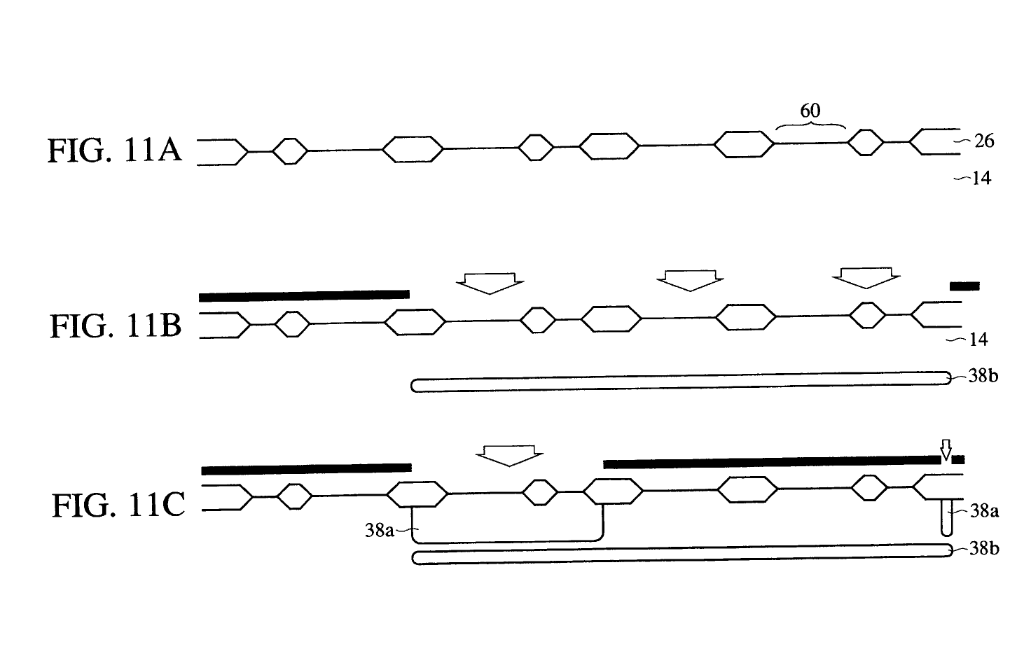

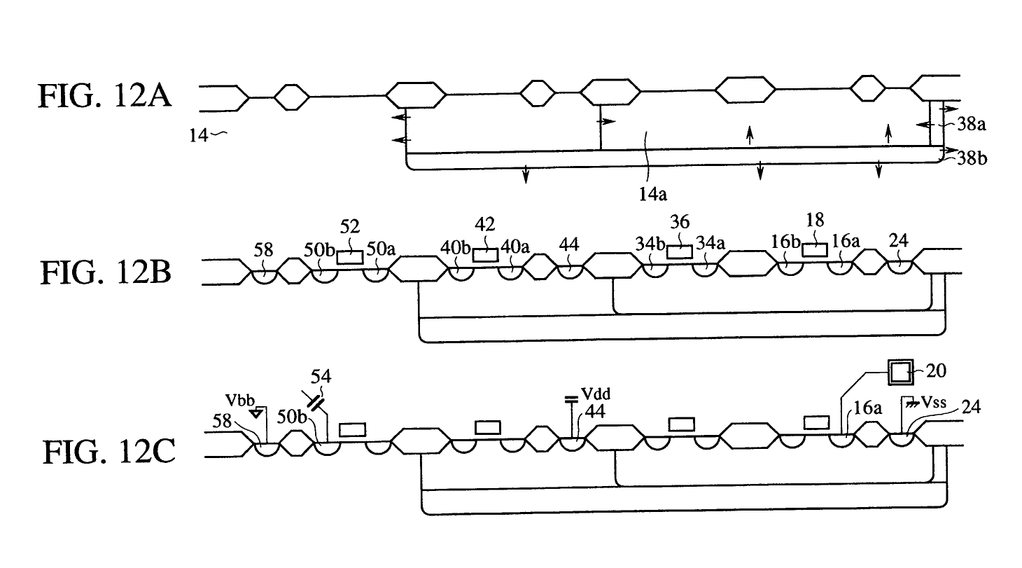

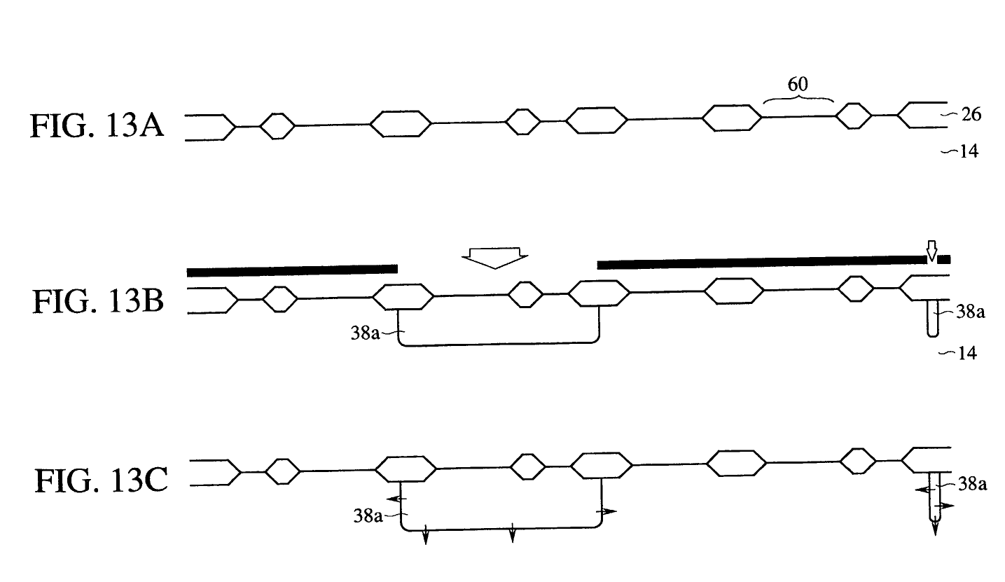

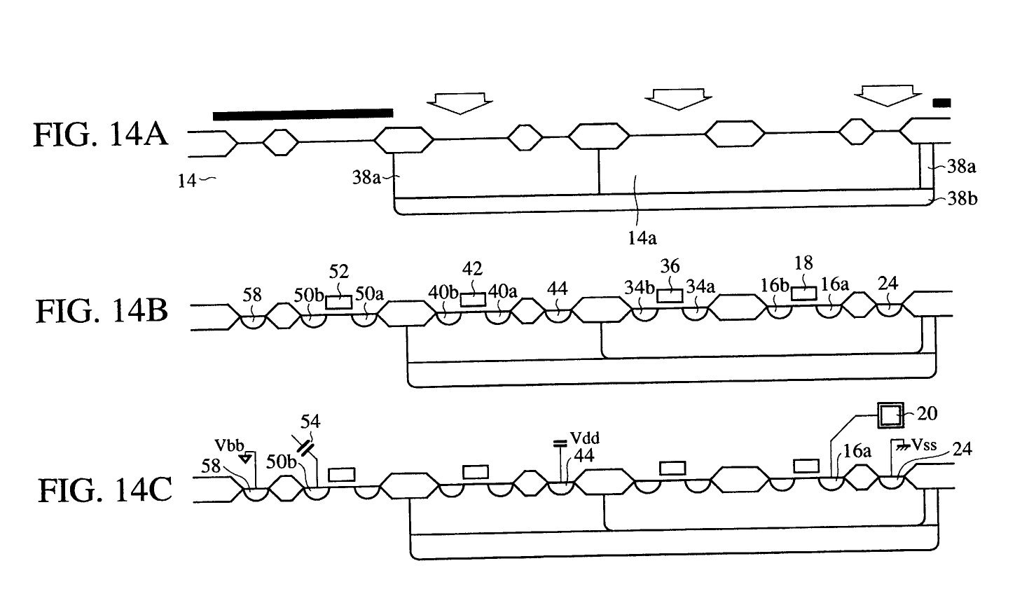

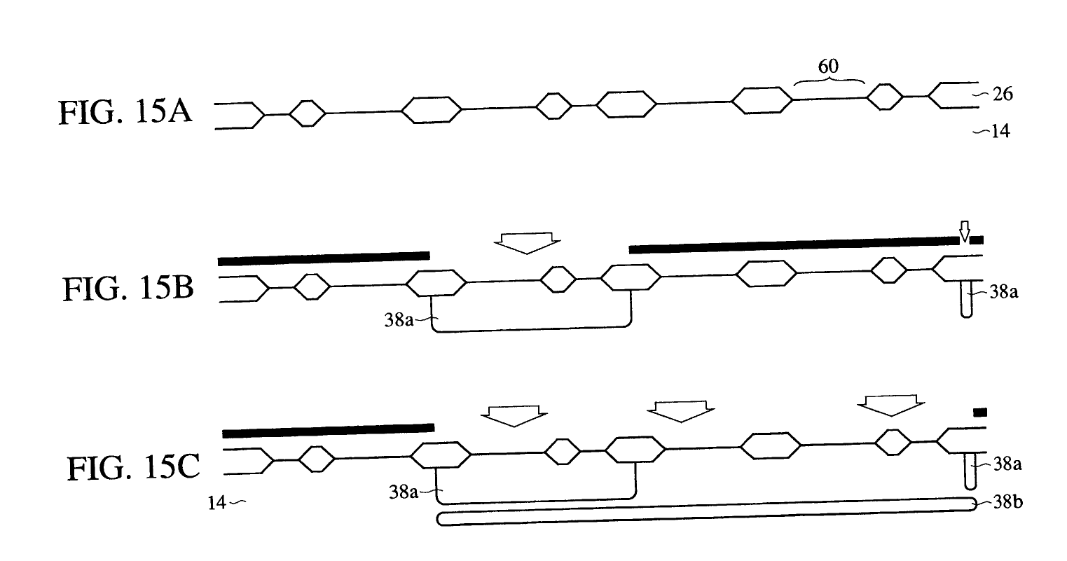

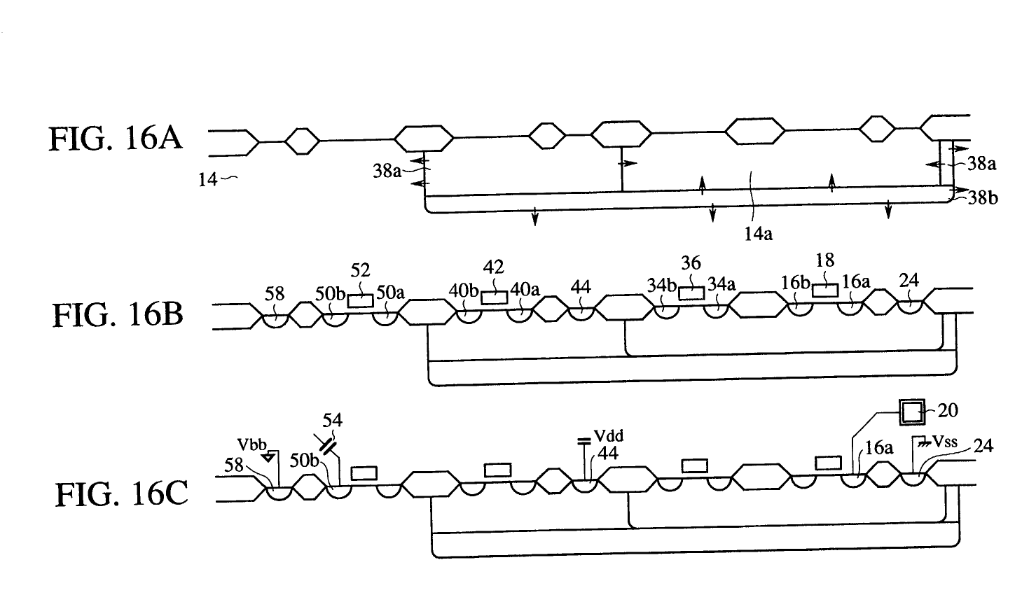

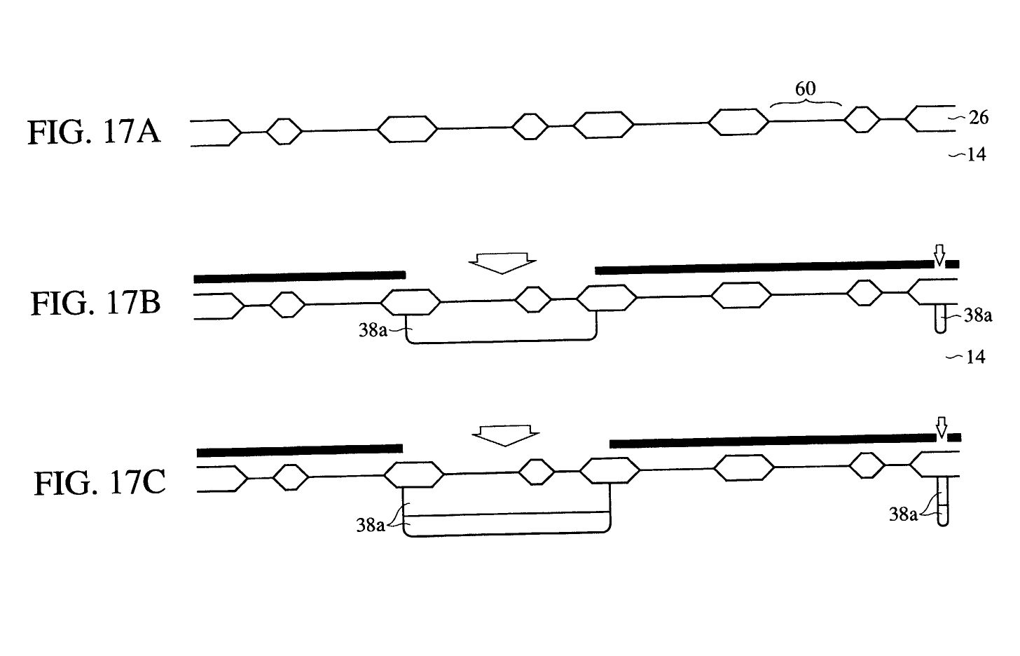

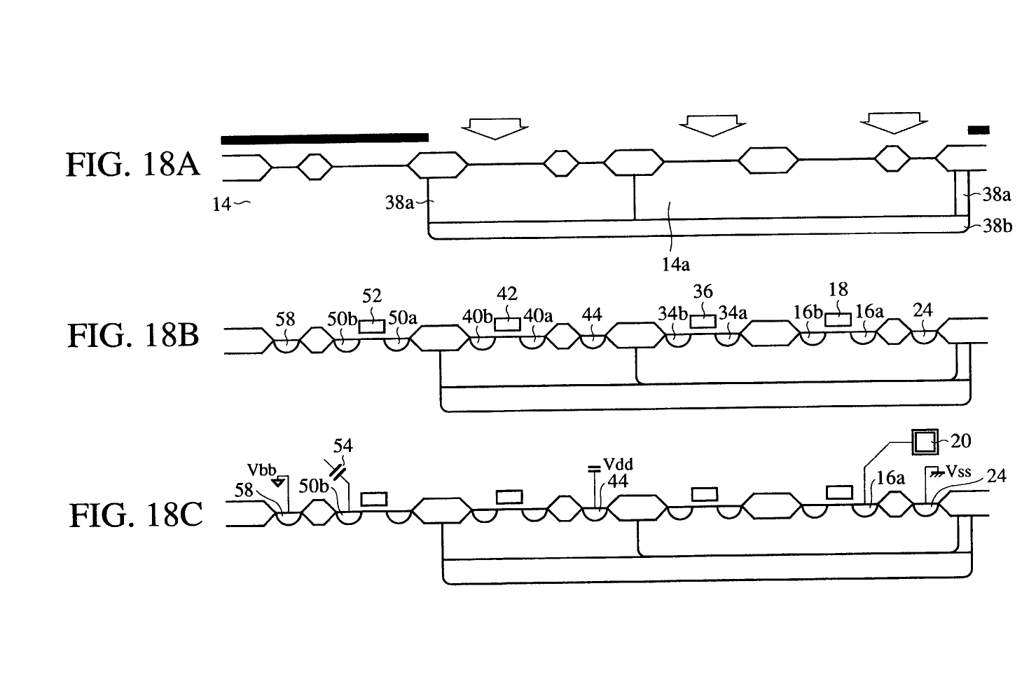

The semiconductor device according to a second embodiment of the present invention and the method for fabricating the semiconductor device will be explained with reference to FIGS. 10 to 18. FIG. 10 is a sectional and a plan view of the semiconductor device according to the present embodiment. FIG. 10A is the sectional view along the line A-A′ in FIG. 10B. FIG. 10B is the plan view in which constituent elements, such as a device isolation film, etc. are omitted. FIGS. 11 and 12 are sectional view of the semiconductor device according to the present embodiment (Part 1) in the steps of the method for fabricating the semiconductor device, which show the method. FIGS. 13 and 14 are sectional view of the semiconductor device according to the present embodiment (Part 2) in the steps of the method for fabricating the semiconductor device, which show the method. FIGS. 15 and 16 are sectional view of the semiconductor device according to the present embodiment (Part 3) in the steps of the method for fabricating the semiconductor device, which show the method. FIGS. 17 and 18 are sectional view of the semiconductor device according to the present embodiment (Part 4) in the steps of the method for fabricating the semiconductor device, which show the method. The same reference numbers of the semiconductor device according to the first embodiment and the method for fabricating the same are represented by the same reference numbers as in the semiconductor device according to the first embodiment and the method for fabricating the same not to repeat or to simplify the explanation.

A major characteristic of the semiconductor device according to the present embodiment is that to prevent a semiconductor substrate from damages by impurity ion implantation, no impurity ions are implanted in a semiconductor device 14 in a region where a cell unit 46 is to be formed. The semiconductor device according to the present embodiment is different from the semiconductor device according to the first embodiment in that the region where an n-semiconductor region 38a and a buried n-semiconductor layer 38b are formed is different from that of the first embodiment, but is the same in the other respects as the semiconductor device according to the first embodiment.

As shown in FIG. 10, the n-semiconductor region 38a is formed in a region near the surface of the semiconductor substrate 14 in a region where a transistor 32 is formed, and is extended over the peripheral portion of a region near the surface of the semiconductor substrate 14 in a region where a transistor 30 and an input/output transistor 12 are formed.

The buried n-semiconductor layer 38b is formed on the semiconductor substrate 14 in regions where the transistors 32, 30 and the input/output transistor 12 are formed, spaced from the surface of the semiconductor substrate 14. The semiconductor substrate 14 in the regions where the input/output transistor 12 and the transistor 30 are formed is electrically isolated from the semiconductor substrate 14 in the other region by the n-semiconductor region 38a and the buried n-semiconductor layer 38b, and forms a p-semiconductor region 14a.

A transistor 48 of the cell unit 46 is formed in a region of the semiconductor substrate 14 without impurity ions implanted. Because the semiconductor substrate 14 without impurity ions implanted is not damaged, leak current between a source/drain diffused layer 50a, 50b of the transistor 48 and the semiconductor substrate 14 is little.

As described above, according to the present embodiment, because the transistor of the cell unit is formed on the semiconductor substrate which is not damaged by impurity ion implantation, leak current from the capacitor through the junction between the source/drain diffused layer of the transistor of the cell unit and the semiconductor substrate can be little, with a result that the semiconductor device can have infrequent rewriting operations for maintaining a charge of the capacitor, and small electric power consumption.

[Method for Fabricating the Semiconductor Device according to the Second Embodiment (Part 1)]

Then, the method for fabricating the semiconductor device according to the present embodiment (Part 1) will be explained with reference to FIGS. 11 and 12.

Fist, as in the first embodiment, a device isolation film 26 is formed on a p-semiconductor substrate 14 to form an active region 60 (see FIG. 11A).

Then, n-impurity ions are implanted at high energy of some MeV by the use of a mask of a pattern which is opened in the regions where the input/output transistor 12 and the transistors 30, 32 are to be formed. Thus, the buried n-semiconductor layer 38b is formed in the region spaced from the surface of the semiconductor substrate 14 (see FIG. 11B).

N-impurity ions are implanted at hundreds keV energy by the use of a mask of a pattern which is opened in the peripheral portion of the region where the transistor 12 and the transistor 30 are to be formed and in the region where the transistor 32 is to be formed. Thus, the n-semiconductor region 38a is formed in a region from the surface of the semiconductor substrate 14 to the vicinity of the buried n-semiconductor layer 38b. (see FIG. 11C).

Next, the n-impurities of the n-semiconductor region 38a and the buried n-semiconductor layer 38b are diffused by heat treatment to connect the n-semiconductor region 38a and the buried n-semiconductor layer 38b with each other. The p-semiconductor region 14a is electrically isolated from the semiconductor substrate 14 by the n-semiconductor region 38a ad the buried n-semiconductor layer 38b (see FIG. 12A).

The steps following these steps are the same as those of the method for fabricating the semiconductor device according to the first embodiment (Part 1).

[Method for Fabricating the Semiconductor Device according to the Second Embodiment (Part 2)]

Then, the method for fabricating the semiconductor device according to the second embodiment (Part 2) will be explained with reference to FIGS. 13 and 14.

The method for fabricating the semiconductor device according to the present embodiment (Part 2) is characterized by forming the active region 60 (see FIG. 13A), forming the n-semiconductor region 38a (see FIG. 13B), then diffusing the n-impurity of the n-semiconductor region 38a (see FIG. 13C), and then forming the buried n-semiconductor layer 38b connected to the n-semiconductor region 38a electrically isolate the n-semiconductor region 14a from the p-semiconductor substrate 14 (see FIG. 14A)

The method for fabricating the semiconductor device according to the present embodiment (Part 2) has a different order of the fabrication steps of the method for fabricating the semiconductor device according to the present embodiment (Part 1) but is the same as the latter in forming the respective constituent elements.

[Method for Fabricating the Semiconductor Device according to the Second Embodiment (Part 3)]

Then, the method for fabricating the semiconductor device according to the second embodiment (Part 3) will be explained with reference to FIGS. 15 and 16.

The method for fabricating the semiconductor device according to the present embodiment (Part 3) is characterized by forming the active region 60 (see FIG. 15A), forming the n-semiconductor region 38a (see FIG. 15B), forming the buried n-semiconductor layer 38b (see FIG. 15C), and then diffusing the n-impurities of the n-semiconductor region 38a and the buried n-semiconductor layer 38b to thereby connect the n-semiconductor region 38a and the buried n-semiconductor layer 38b with each other to electrically isolate the p-semiconductor region 14a from the semiconductor substrate 14.

The method for fabricating the semiconductor device according to the present embodiment (Part 3) has a different order of the fabrication steps of the method for fabricating the semiconductor device according to the present embodiment (Part 1) but is the same as the latter in forming the respective constituent elements.

[Method for Fabricating the Semiconductor Device according to the Second Embodiment (Part 4)]

Then, the method for fabricating the semiconductor device according to the second embodiment (Part 4) will be explained with reference to FIGS. 17 and 18.

The method for fabricating the semiconductor device according to the present embodiment (Part 4) is characterized by forming the active region 60 (see FIG. 17A), then forming the n-semiconductor region 38a (see FIG. 17B), implanting an n-impurity at high energy to form the n-semiconductor region 38a deep from surface of the semiconductor substrate 14 (see FIG. 17C), and forming the buried n-semiconductor layer 38b connected to the n-semiconductor region 38a to electrically isolate the p-semiconductor region 14a from the semiconductor substrate 14 (see FIG. 18A). Because the n-semiconductor region 38a is formed deep from the surface of the semiconductor substrate 14, the n-semiconductor region 38a and the buried n-semiconductor layer 38b can be connected with each other without impurity diffusion by heat treatment.

The method for fabricating the semiconductor device according to the present embodiment (Part 4) has a different order of the fabrication steps of the method for fabricating the semiconductor device according to the present embodiment (Part 1) but is the same as the latter in forming the respective constituent elements.

[A Third Embodiment]

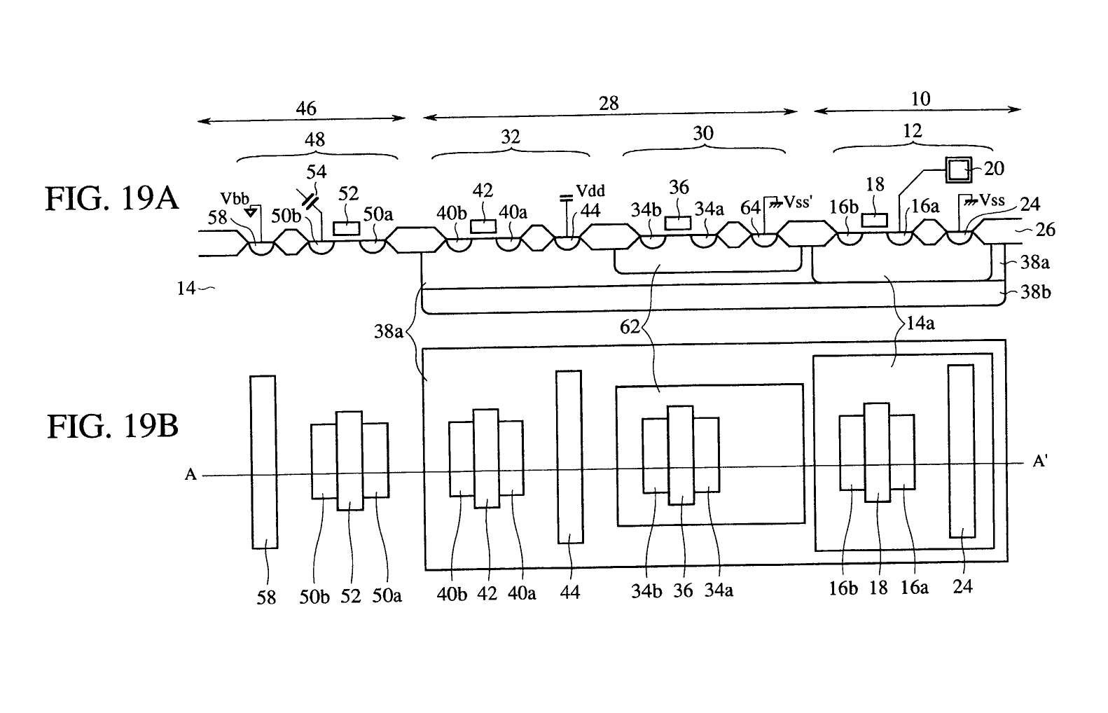

The semiconductor device according to a third embodiment and the method for fabricating the semiconductor device will be explained with reference to FIGS. 19 to 27.

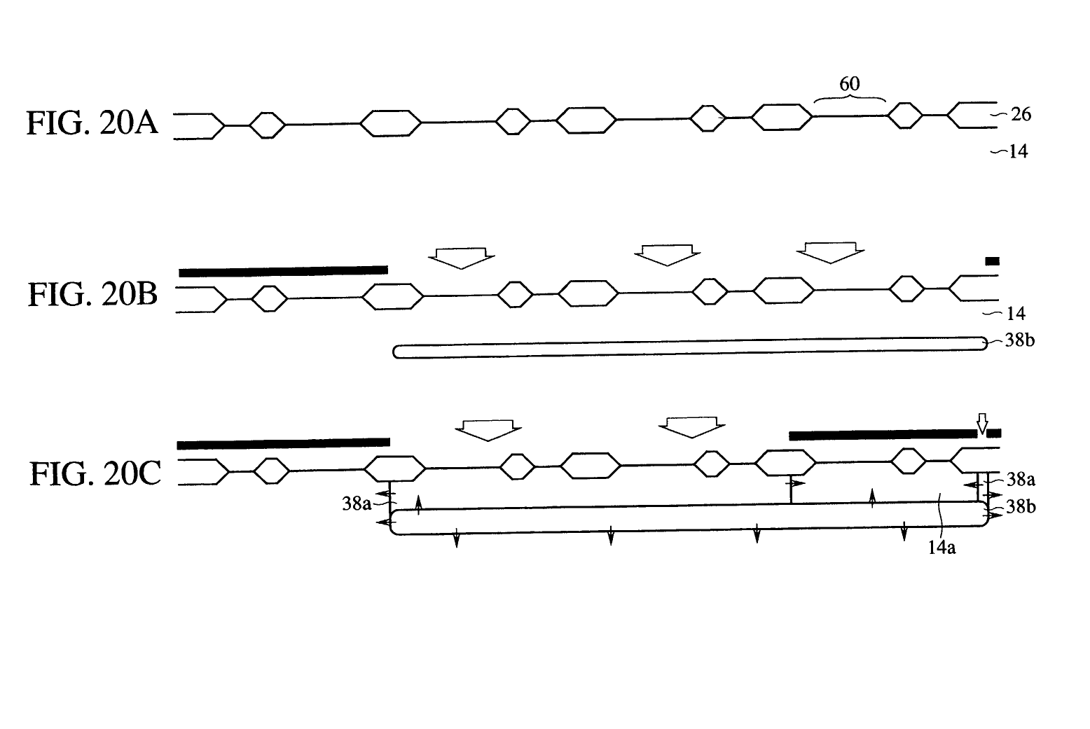

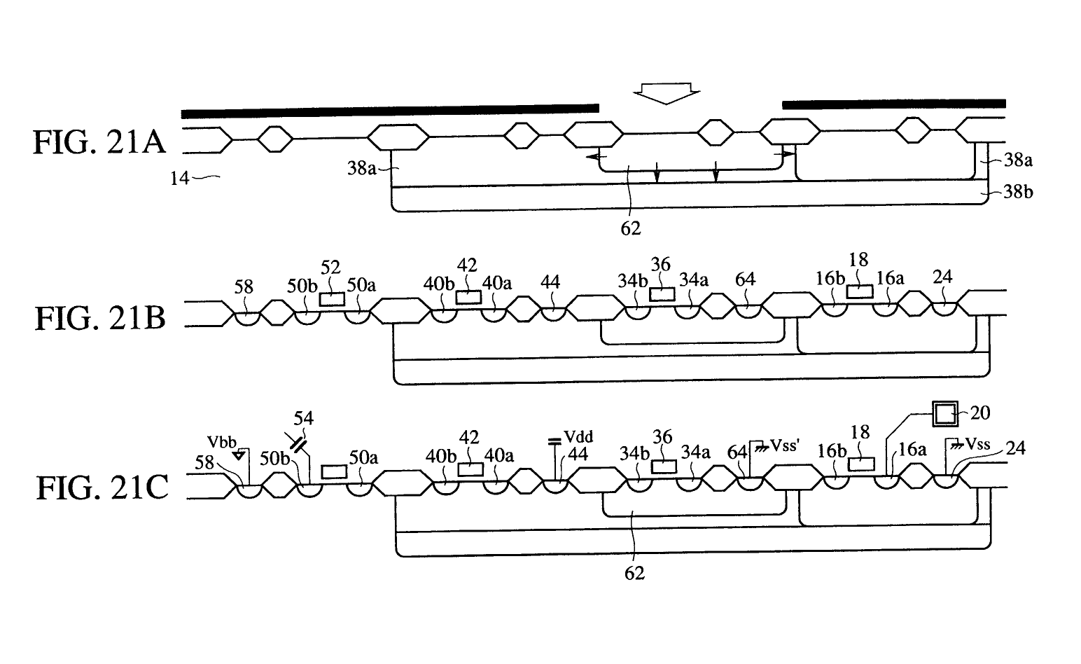

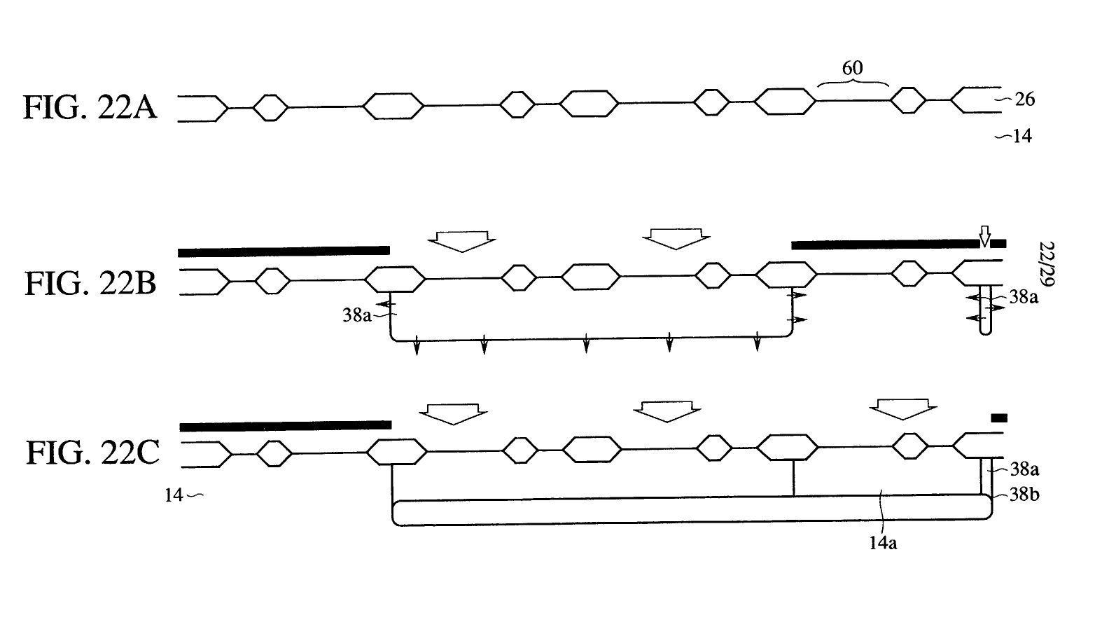

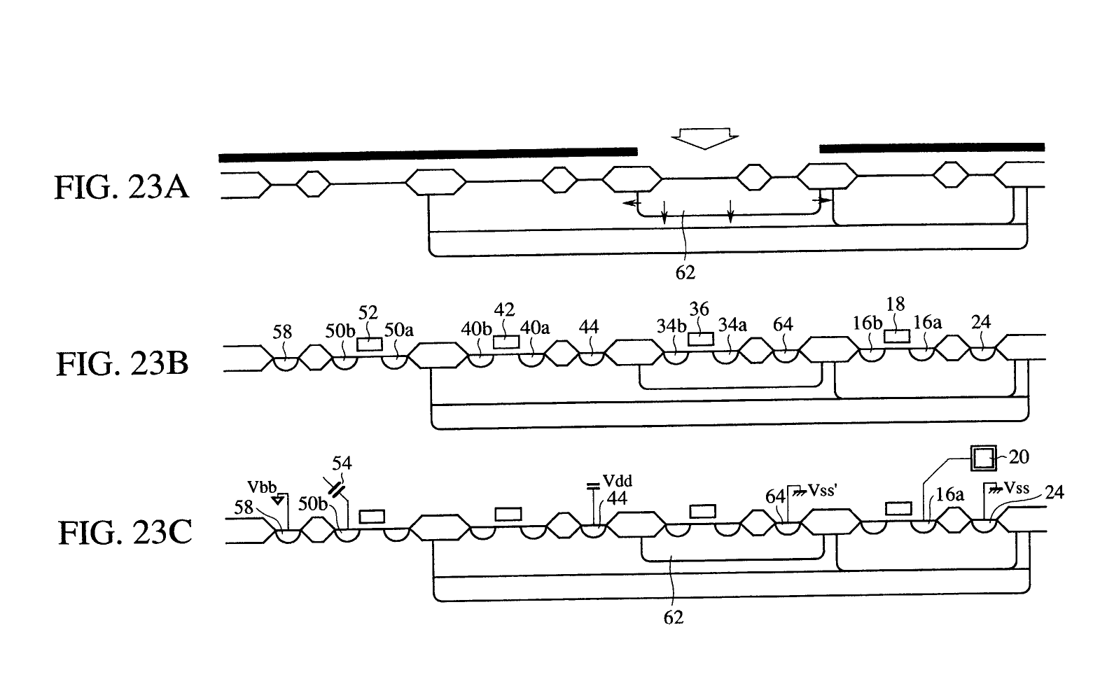

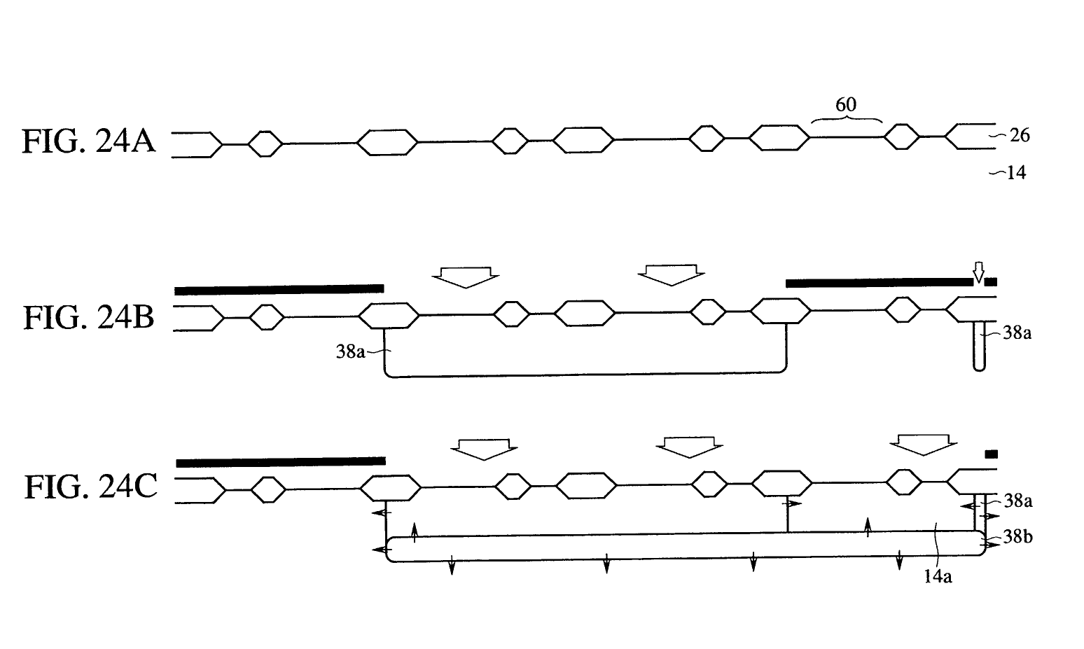

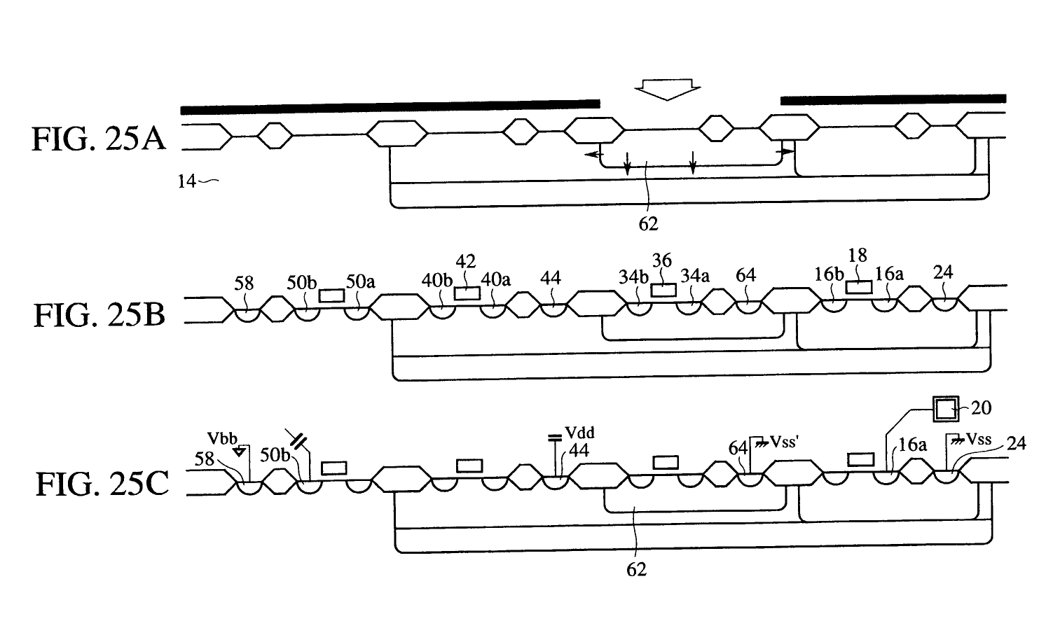

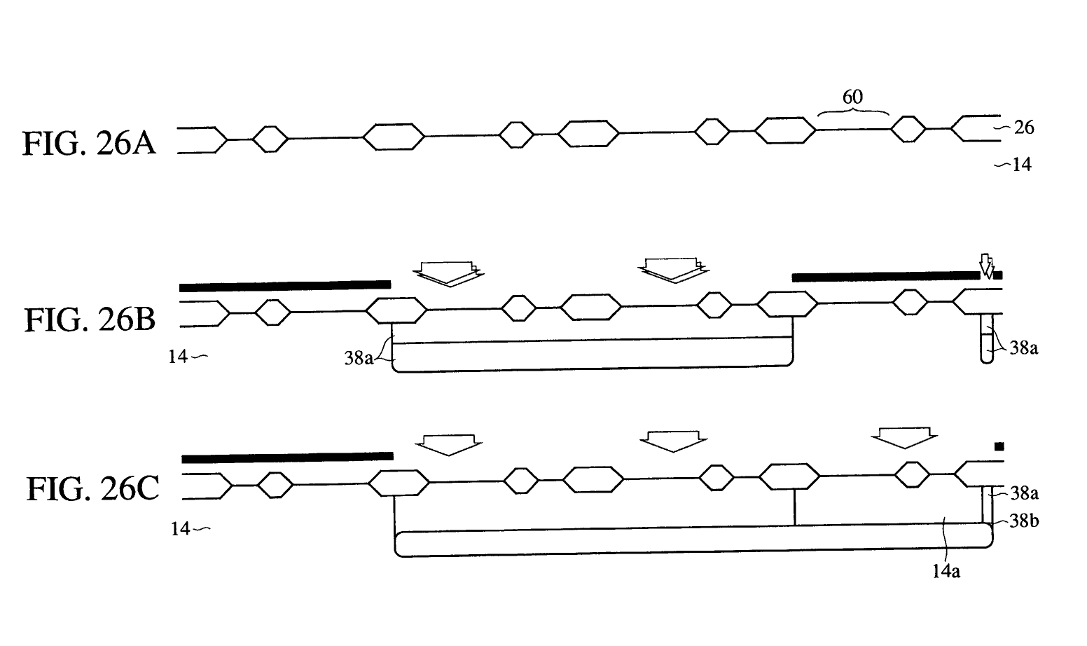

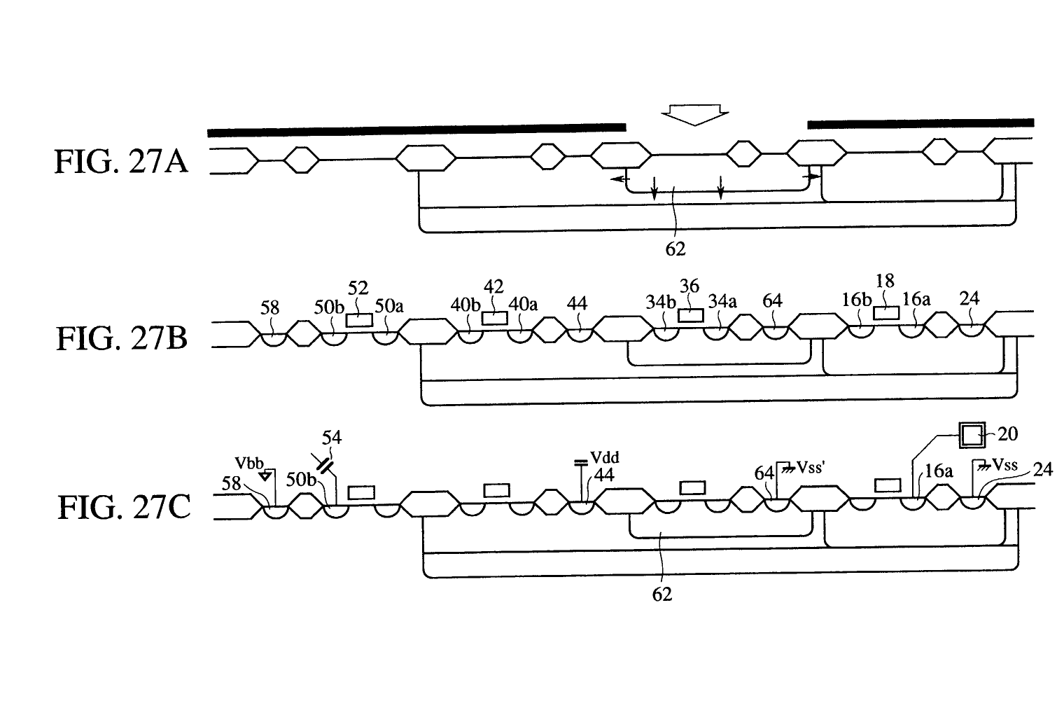

FIG. 19 is a sectional and a plan view of the semiconductor device according to the present embodiment. FIG. 19A is the sectional view along the line A-A′ in FIG. 19B. FIG. 19B is the plan view in which constituent elements, such as a device isolation film, etc. are omitted. FIGS. 20 and 21 are sectional view of the semiconductor device according to the present embodiment (Part 1) in the steps of the method for fabricating the semiconductor device, which show the method. FIGS. 22 and 23 are sectional view of the semiconductor device according to the present embodiment (Part 2) in the steps of the method for fabricating the semiconductor device, which show the method. FIGS. 24 and 25 are sectional view of the semiconductor device according to the present embodiment (Part 3) in the steps of the method for fabricating the semiconductor device, which show the method. FIGS. 26 and 27 are sectional view of the semiconductor device according to the present embodiment (Part 4) in the steps of the method for fabricating the semiconductor device, which show the method. The same reference numbers of the semiconductor device according to the first or the second embodiment and the method for fabricating the same shown in FIGS. 1 to 18 are represented by the same reference numbers as in the semiconductor device according to the first embodiment and the method for fabricating the same not to repeat or to simplify the explanation.

A major characteristic of the semiconductor device according to the present embodiment is that a transistor 30 is formed on a p-well 62 electrically isolated from a p-semiconductor region 14a. The semiconductor device according to the present embodiment is different from the semiconductor device according to the second embodiment in that the region where an n-semiconductor region 38a is formed is different from that of the latter and in that a p-well 62 is formed by further implanting a p-impurity partially in the n-semiconductor region 38a, and a transistor 30 is formed on the p-well 62, but is the same as the semiconductor device according to the second embodiment in the other respects.

As shown in FIG. 19, the n-semiconductor region 38a is formed in a region near the surface of a semiconductor substrate 14 in a region where transistors 30, 32 are formed, and is extended over the peripheral portion of a region near the surface of the semiconductor substrate 14 in a region where an input/output transistor 12 is formed.

The semiconductor substrate 14 in the region where the input/output transistor 12 is formed is electrically isolated from the semiconductor substrate 14 in the rest region by the n-semiconductor region 38a and the buried n-semiconductor layer 38b, and forms a p-semiconductor region 14a.

The p-well 62 is formed in a part of the n-semiconductor region 38a in the region where the transistor 30 is formed, by implanting p-impurity ions in a high concentration. The n-channel transistor 30 is formed on the p-well 62. The p-well 62 is connected to a voltage Vss' electrically isolated from a ground voltage Vss, through a contact layer 64 heavily doped with a p-impurity.

As described above, according to the present embodiment, the input/output transistor is formed on the p-semiconductor region, the transistor is formed on the p-well electrically isolated from the p-semiconductor region, and the p-semiconductor region and the p-well are connected respectively to the voltages Vss, Vss' electrically isolated from each other, whereby even when a minus abnormal voltage, for example, is applied to a source/drain diffused layer of the input/output transistor, a transistor of a control unit is prevented from erroneous operations. Accordingly, in a case that the transistor of the control unit is used for control of a transistor of a cell unit, the transistor of the control unit is not caused to make erroneous operations, and information of the memory cells are protected from breakage.

[Method for Fabricating the Semiconductor Device According to the Third Embodiment (Part 1)]

The method for fabricating the semiconductor device according to the third embodiment (Part 1) will be explained with reference to FIGS. 20 to 21.

First, as in the first embodiment, a device isolation film 26 is formed on a p-semiconductor substrate 14 to for an active region 60 (see FIG. 20A).

Then, n-impurity ions are implanted at high energy of some MeV by the use of a mask of a pattern which is opened in regions where an input/output transistor 12, and transistors 30, 32 are to be formed. Thus the buried n-semiconductor layer 38b is formed in a region spaced from the surface of the semiconductor substrate 14 (see FIG. 20B).

Next, n-impurity ions are implanted at hundreds keV energy by the use of a mask having a pattern which is opened in the peripheral portion of the region where the input/output transistor 12 is to be formed and in the regions for the transistors 30, 32 are to be formed. Thus, the n-semiconductor region 38a is formed from the surface of the semiconductor substrate 14 to the vicinity of the buried n-semiconductor layer 38b. Then, the n-impurities of the n-semiconductor region 38a and the buried n-semiconductor layer 38b are diffused by heat treatment to connect the n-semiconductor region 38a and the n-semiconductor layer 38b with each other. The p-semiconductor region 14a is electrically isolated from the semiconductor substrate 14 by the n-semiconductor region 38a and the buried n-semiconductor layer 38b (see FIG. 20C).

Next, a p-impurity is implanted in a high concentration in a part of the n-semiconductor region 38a in a region where the transistor 30 is to be formed to form the p-well 62, and then heat treatment is performed (see FIG. 21A).

Then, as in the method for fabricating the semiconductor device according to the first embodiment, the gate electrodes 18, 36, 42, 52, the source/drain diffused layer 16a, 16b, 34a, 34b, 50a, 50b, and a source/drain diffused layer 40a, 40b are sequentially formed. Then, p-impurity ions are implanted in a high concentration by the use of a mask patterned in shapes of the contact layers 24, 58, 64 to form the contact layers 24, 58, 64. Then, as in the method for fabricating the semiconductor device according to the first embodiment, the contact layer 44 is formed (see FIG. 21B).

Then, as in the fist embodiment, an insulation film (not shown) is formed on the entire surface of the semiconductor substrate 14. Next, contact holes are formed in the source/drain layer 16a, 50b and on the contact layers 24, 44, 58, 64. Next, wiring is performed by aluminum vapor deposition or others to connect the source/drain diffused layer 16a to the pad 20, the source/drain diffused layer 50b to a capacitor 54, and the contact layers 24, 44, 58, 64 respectively to the prescribed voltages Vss, Vdd, Vbb, Vss' (see FIG. 21C).

Thus, the semiconductor device according to the present embodiment is fabricated.

[Method for Fabricating the Semiconductor Device According to the Third Embodiment (Part 2)]

Then, the method for fabricating the semiconductor device according to the third embodiment (Part 2) will be explained with reference to FIGs.22 and 23.

The method for fabricating the semiconductor device according to the present embodiment (Part 2) is characterized by forming the active region 60 (see FIG. 22A), then forming the n-semiconductor region 38a, next diffusing the n-impurity of the n-semiconductor region 38a (see FIG. 22B), and forming the buried n-semiconductor layer 38b connected to the n-semiconductor region 38a to electrically isolate the p-semiconductor region 14a from the p-substrate 14 (see FIG. 22C).

The method for fabricating the semiconductor device according to the present embodiment (Part 2) has a different order of the fabrication steps of the method for fabricating the semiconductor device according to the present embodiment (Part 1) but is the same as the latter in forming the respective constituent elements.

[Method for Fabricating the Semiconductor Device according to the Third Embodiment (Part 3)]

Then, the method for fabricating the semiconductor device according to the third embodiment (Part 3) will be explained with reference to FIGS. 24 and 25.

The method for fabricating the semiconductor device according to the present embodiment (Part 3) is characterized by forming the active region 60 (see FIG. 24A), forming the n-semiconductor region 38a (see FIG. 24B), and forming the buried n-semiconductor layer 38b and diffusing the impurities of the n-semiconductor region 38a and the buried n-semiconductor layer 38b to thereby connect the n-semiconductor region 38a and the buried n-semiconductor layer 38b with each other to electrically isolate the p-semiconductor region 14a from the semiconductor substrate 14 (see FIG. 24C).

The method for fabricating the semiconductor device according to the present embodiment (Part 3) has a different order of the fabrication steps of the method for fabricating the semiconductor device according to the present embodiment (Part 1) but is the same as the latter in forming the respective constituent elements.

[Method for Fabricating the Semiconductor Device according to the Third Embodiment (Part 4)]

Then, the method for fabricating the semiconductor device according to the third embodiment (Part 4) will be explained with reference to FIGS. 26 and 27.

The semiconductor device according to the present embodiment is characterized by forming the active region 60 (see FIG. 26A), then forming the n-semiconductor region 38a and then implanting n-impurity at high energy to form the n-semiconductor region 38a deep from the surface of the semiconductor substrate 14 (see FIG. 26B), and then forming the buried n-semiconductor layer 38b connected to the n-semiconductor region 38a to electrically isolate the p-semiconductor region 14a from the semiconductor substrate 14 (see FIG. 26C). Because the n-semiconductor region 38a is formed deep from the surface of the semiconductor substrate 14a, the n-semiconductor region 38a and the buried n-semiconductor layer 38b are connected with each other without diffusing the impurities by heat treatment.

The method for fabricating the semiconductor device according to the present embodiment (Part 4) has a different order of the fabrication steps of the method for fabricating the semiconductor device according to the present embodiment (Part 1) but is the same as the latter in forming the respective constituent elements.

[A Modification]

The present invention is not limited to the above-described embodiment and cover various modifications.

For example, conduction types of the semiconductor substrate and the respective constituent members are not limited to those of the above-described embodiments and can be suitably selected.

Regions of the respective semiconductor regions and regions where the well, etc. are formed are not limited to the those of the above-described embodiments and can be formed at various locations.

In the first to the third embodiments, a voltage Vdd is not essentially different from a voltage Vss or a voltage Vbb, and can be the same as a voltage Vss, a voltage Vdd or a voltage Vbb.

In the third embodiment, a voltage Vss' is not essentially different from a voltage Vss, a voltage Vdd or a voltage Vbb, and may be the same as a voltage Vss, a voltage Vdd or a voltage Vbb.

What is claimed is:

1. A semiconductor device comprising:
a semiconductor substrate of a first conduction type;
a buried semiconductor layer of a second conduction type formed in a first region of the semiconductor substrate, spaced from a surface of the semiconductor substrate;
a semiconductor region of the second conduction type extending from the surface of the semiconductor substrate to a peripheral portion of the buried semiconductor layer; and
a semiconductor region of the first conduction type formed in the semiconductor substrate surrounded by the buried semiconductor layer and the semiconductor region of the second conduction type.

2. A semiconductor device according to claim 1, further comprising
a first semiconductor element formed in the first conduction type region; and
a second semiconductor element formed in a second region different from the first region of the semiconductor substrate,
the first conduction type semiconductor region being connected to a first potential,
the second region of the semiconductor substrate being connected to a second potential different from the first potential.

3. A semiconductor device according to claim 2, wherein
the second conduction type semiconductor region is extended over a third region adjacent to the first region of the semiconductor substrate;
the semiconductor device further comprises a third semiconductor element formed in the third region of the second conduction type semiconductor region; and
the second conduction type semiconductor region is connected to a third potential different at least the first potential or the second potential.

4. A semiconductor device according to claim 3, further comprising
a well of the first conduction type formed in a fourth region in the third region; and
a fourth semiconductor element formed in the first conduction type well, and
the first conduction type well being connected to a fourth potential different from at least the first potential.

5. A semiconductor device according to claim 2, wherein
the first semiconductor element and/or the second semiconductor element is a memory cell.

6. A semiconductor device according to claim 3, wherein
the first semiconductor element and/or the second semiconductor element is a memory cell.

7. A semiconductor device according to claim 4, wherein
the first semiconductor element and/or the second semiconductor element is a memory cell.

8. A method for fabricating a semiconductor device comprising:
a buried semiconductor layer forming step of implanting at first energy impurity ions of a second conduction type in a first region of a semiconductor substrate of a first conduction type to form a buried semiconductor layer of the second conduction type in the semiconductor substrate, spaced from a surface of the semiconductor substrate; and
a second conduction type semiconductor region forming step of implanting impurity ions of the second conduction type in a peripheral portion of the first region of the semiconductor device at second energy which is lower than the first energy to form a semiconductor region of the second conduction type extended to the buried semiconductor layer.

9. A method for fabricating a semiconductor device comprising:
a buried semiconductor layer forming step of implanting at first energy impurity ions of a second conduction type in a first region of a first conduction type semiconductor substrate to form a buried semiconductor layer of the second conduction type in the semiconductor substrate, spaced from a surface of the semiconductor substrate;
a second conduction type semiconductor region forming step of implanting impurity ions of the second conduction type in a peripheral portion of the first region of the semiconductor device at second energy which is lower than the first energy to form a semiconductor region of the second conduction type in a region which is deep to a prescribed level from the surface of the semiconductor substrate; and
a heat treatment step of performing a heat treatment to diffuse the impurity ions in the buried semiconductor layer and in the second conduction type semiconductor region to connect the buried semiconductor layer and the second conduction type semiconductor region with each other.

10. A method for fabricating a semiconductor device comprising:
a second conduction type semiconductor region forming step of implanting impurity ions of a second conduction type at first energy in a peripheral portion of a first region of a semiconductor substrate of a first conduction type to form a semiconductor region of the second conduction type in a region which is deep to a prescribed level from a surface of the semiconductor substrate;
a heat treatment step of performing a heat treatment to diffuse the impurity ions in the second conduction type semiconductor region; and
a buried semiconductor layer forming step of implanting impurity ions of the second conduction type in the first region of the semiconductor substrate at second energy which is higher than the first energy to form a buried semiconductor layer of the second conduction type connected to the second conduction type semiconductor region, spaced from the surface of the semiconductor substrate.

11. A method for fabricating a semiconductor device comprising:
a second conduction type semiconductor region forming step of implanting impurity ions of a second conduction type at first energy in a peripheral portion of a first region of a semiconductor substrate of a first conduction type to form a semiconductor region of the second conduction type in a region which is deep to a prescribed level from a surface of the semiconductor substrate;
a buried semiconductor layer forming step of implanting impurity ions of the second conduction type in the first region of the semiconductor substrate at a second energy which is higher than the first energy to form a buried semiconductor layer of the second conduction type spaced form the surface of the semiconductor substrate; and
a heat treatment step of performing a heat treatment to diffuse the impurity ions in the second conduction type semiconductor region and in the buried semiconductor layer to connect the second conduction type semiconductor region and the buried semiconductor layer with each other.

12. A method for fabricating a semiconductor device comprising:
a second conduction type semiconductor region forming step of implanting impurity ions of a second conduction type at first energy in a peripheral portion of a first region of a semiconductor substrate of a first conduction type at first energy to form a semiconductor region of the second conduction type, then implanting impurity ions of the second conduction type in the peripheral portion at second energy which is higher than the first energy to form the second conduction type semiconductor region deeper from the surface of the semiconductor substrate; and
a buried semiconductor layer forming step of implanting impurity ions of the second conduction type in the first region of the semiconductor substrate at third energy which is higher than the second energy to form a buried semiconductor layer of the second conduction type connected to the second conduction type semiconductor region, spaced from the surface of the semiconductor substrate.

13. A method for fabricating a semiconductor device according to claim 8, wherein
in the second conduction type semiconductor region forming step, a semiconductor region of the second conduction type is also formed in a second region which is adjacent to the first region of the semiconductor substrate.

14. A method for fabricating a semiconductor device according to claim 9, wherein
in the second conduction type semiconductor region forming step, a semiconductor region of the second conduction type is also formed in a second region which is adjacent to the first region of the semiconductor substrate.

15. A method for fabricating a semiconductor device according to claim 10, wherein
in the second conduction type semiconductor region forming step, a semiconductor region of the second conduction type is also formed in a second region which is adjacent to the first region of the semiconductor substrate.

16. A method for fabricating a semiconductor device according to claim 11, wherein
in the second conduction type semiconductor region forming step, a semiconductor region of the second conduction type is also formed in a second region which is adjacent to the first region of the semiconductor substrate.

17. A method for fabricating a semiconductor device according to claim 12, wherein
in the second conduction type semiconductor region forming step, a semiconductor region of the second conduction type is also formed in a second region which is adjacent to the first region of the semiconductor substrate.

18. A method for fabricating a semiconductor device according to claim 13, further comprising
a well forming step of implanting a high concentration of impurity ions of the first conduction type in a prescribed region of the second region to form a well of the first conduction type.

19. A method for fabricating a semiconductor device according to claim 14, further comprising
a well forming step of implanting a high concentration of impurity ions of the first conduction type in a prescribed region of the second region to form a well of the first conduction type.

20. A method for fabricating a semiconductor device according to claim 15, further comprising
a well forming step of implanting a high concentration of impurity ions of the first conduction type in a prescribed region of the second region to form a well of the first conduction type.

21. A method for fabricating a semiconductor device according to claim 16, further comprising
a well forming step of implanting a high concentration of impurity ions of the first conduction type in a prescribed region of the second region to form a well of the first conduction type.

22. A method for fabricating a semiconductor device according to claim 17, further comprising
a well forming step of implanting a high concentration of impurity ions of the first conduction type in a prescribed region of the second region to form a well of the first conduction type.
